(19) United States
(12) Patent Application Publication
(10) Pub. No.: US 2026/0020338 A1
(43) Pub. Date: Jan. 15, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Wookhyun Kwon, Suwon-si (KR); Seokhyeon Yoon, Suwon-si (KR); Byoung Hak Hong, Suwon-si (KR)

(21) Appl. No.: 19/046,686

(22) Filed: Feb. 6, 2025

(30) Foreign Application Priority Data
Jul. 11, 2024 (KR) 10-2024-0091761

(51) Int. Cl. H10D 84/85; H10D 30/00; H10D 30/01; H10D 30/43; H10D 62/10; H10D 62/13; H10D 64/27; H10D 84/01

(52) U.S. Cl. CPC H10D 84/856; H10D 30/014; H10D 30/0191; H10D 30/43; H10D 30/502; H10D 62/121; H10D 62/151; H10D 64/516; H10D 84/0167; H10D 84/0184; H10D 84/851

(57) ABSTRACT

A semiconductor device includes first source/drain patterns spaced apart in a first direction on a first region of a substrate, a first gate structure extending in a second direction intersecting the first direction, second source/drain patterns spaced apart in the first direction on a second region of the substrate, a second gate structure extending in the second direction, a first internal gate spacer between the first gate structure and one of the first source/drain patterns, and a second internal gate spacer between the second gate structure and one of the second source/drain patterns. The first and second internal gate spacers have first and second thicknesses, respectively, in the first direction. The first thickness of the first internal gate spacer at a center point thereof along the second direction is different from the second thickness of the second internal gate spacer at a center point thereof along the second direction.

### CROSS-REFERENCE TO RELATED APPLICATIONS

This application claims priority to and the benefit of Korean Patent Application No. 10-2024-0091761 filed in the Korean Intellectual Property Office on Jul. 11, 2024, the entire contents of which are incorporated herein by reference.

### BACKGROUND OF THE INVENTION

The present disclosure relates to a semiconductor device and a manufacturing method of a semiconductor device.

A semiconductor is a material that belongs to a middle region between a conductor and an insulator and refers to a material that conducts electricity under predetermined conditions. Using these semiconductor materials, various semiconductor devices may be manufactured, for example, memory devices, etc. These semiconductor devices may be used in various electronic devices.

As the electronics industry develops, the performance demands for semiconductor devices are increasing. For example, demands for high reliability, higher speed and/or multifunctionality for the semiconductor devices are increasing. In order to meet these demands, structures within the semiconductor devices are becoming increasingly complex and integrated.

### SUMMARY OF THE INVENTION

Embodiments of the present disclosure provide high reliability semiconductor devices and manufacturing methods thereof according to the characteristics of each device.

A semiconductor device according to some embodiments may include a substrate including a first region and a second region, first source/drain patterns spaced apart from each other in a first direction on the first region of the substrate, first channel patterns between the first source/drain patterns, a first gate structure at least partially surrounding the first channel patterns and extending in a second direction intersecting the first direction, wherein the first channel patterns are spaced apart from each other in a third direction perpendicular to the first and second directions, second source/drain patterns spaced apart from each other in the first direction on the second region of the substrate, second channel patterns spaced apart from each other in the third direction and between the second source/drain patterns, a second gate structure at least partially surrounding the second channel patterns and extending in the second direction, a first internal gate spacer between the first gate structure and a first one of the first source/drain patterns, and a second internal gate spacer between the second gate structure and a first one of the second source/drain patterns, wherein the first internal gate spacer has a first thickness in the first direction, and the second internal gate spacer has a second thickness in the first direction, wherein the first thickness of the first internal gate spacer at a center point thereof along the second direction is different from the second thickness of the second internal gate spacer at a center point thereof along the second direction, wherein the first internal gate spacer includes a side surface that faces the first one of the first source/drain patterns in the first direction and has a concave shape in a cross-sectional view, and wherein the second internal gate spacer includes a side surface that faces the first one of the second source/drain patterns in the first direction and has a concave shape in a cross-sectional view.

A manufacturing method of a semiconductor device according to some embodiments may include forming first source/drain patterns spaced apart from each other in a first direction on a first region of a substrate, and second source/drain patterns spaced apart from each other in the first direction on a second region of the substrate, forming first channel patterns between the first source/drain patterns and having a first width in a second direction intersecting the first direction, and second channel patterns between the second source/drain patterns and having a second width in the second direction that is different from the first width, forming first internal spaces at least partially surrounded by the first source/drain patterns, and second internal spaces at least partially surrounded by the second source/drain patterns, forming a first internal gate spacer on a side surface of a first one of the first source/drain patterns and in a first one of the first internal spaces, and a second internal gate spacer on a side surface of a first one of the second source/drain patterns and in a first one of the second internal spaces, the first internal gate spacer and the second internal gate spacer having a first thickness and a second thickness, respectively, in the first direction, and forming a first gate electrode in the first internal spaces, and a second gate electrode in the second internal spaces, wherein the first thickness of the first internal gate spacer at a center point thereof along the second direction is different from the second thickness of the second internal gate spacer at a center point thereof along the second direction.

A manufacturing method of a semiconductor device according to some embodiments may include forming first source/drain patterns spaced apart from each other in a first direction on a first region of a substrate, and second source/drain patterns spaced apart from each other in the first direction on a second region of the substrate, forming first internal spaces at least partially surrounded by first channel patterns between the first source/drain patterns and having a first length in a third direction perpendicular to an upper surface of the substrate, and second internal spaces at least partially surrounded by second channel patterns between the second source/drain patterns and having a second length in the third direction that is different from the first length, forming a first internal gate spacer on a side surface of a first one of the first source/drain patterns and in a first one of the first internal spaces, and a second internal gate spacer on a side surface of a first one of the second source/drain patterns and in a first one of the second internal spaces, the first internal gate spacer and the second internal gate spacer having a first thickness and a second thickness, respectively, in the first direction, and forming a first gate electrode in the first internal spaces, and a second gate electrode in the second internal spaces, wherein the first thickness of the first internal gate spacer at a center point thereof along a second direction intersecting the first direction is different from the second thickness of the second internal gate spacer at a center point thereof along the second direction.

According to embodiments of the present disclosure, the reliability according to the characteristics of each semiconductor device may be secured by varying the thickness of the gate spacer.

### BRIEF DESCRIPTION OF THE DRAWINGS

FIG. 1 is a top plan view showing a semiconductor device according to some embodiments.

FIG. 2 is a cross-sectional view taken along lines A-A′ and B-B′ of FIG. 1.

FIG. 3 is a cross-sectional view taken along lines C-C′ and D-D′ of FIG. 1.

FIG. 4 is a cross-sectional view taken along lines E-E′ and F-F′ of FIG. 1.

FIG. 5 is an enlarged view of a region M and a region N of FIG. 2.

FIGS. 6 to 10 are enlarged views to explain a method of forming a region M and a region N of FIG. 2 according to some embodiments.

FIG. 11 is a top plan view showing a semiconductor device according to some further embodiments.

FIG. 12 is a cross-sectional view taken along lines G-G′ and H-H′ of FIG. 11.

FIG. 13 is an enlarged view of a region P and a region Q of FIG. 12.

FIGS. 14 to 18 are enlarged views to explain a method of forming a region P and a region Q of FIG. 12 according to some further embodiments.

### DETAILED DESCRIPTION

The present disclosure will be described more fully hereinafter with reference to the accompanying drawings, in which example embodiments of the present disclosure are shown. As those skilled in the art will realize, the described embodiments may be modified in various different ways, all without departing from the scope of the present disclosure.

In order to clearly explain the present disclosure, portions that are not directly related to the present disclosure may be omitted, and the same reference numerals are attached to the same or similar constituent elements throughout the entire specification.

In the drawings, the thicknesses of layers, films, panels, regions, etc., may be exaggerated for better understanding and ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

In the drawings, a semiconductor device according to some embodiments may include a transistor including a nano sheet, or an MBCFET™ (Multi-Bridge Channel Field Effect Transistor), but this is shown as an example and the present disclosure is not limited thereto. It will be understood that semiconductor devices according to some embodiments may include a transistor including nano wires, a fin-type transistor (FinFET) including a channel region in a fin-type pattern shape, a tunneling transistor (tunneling FET), a 3D stack field effect transistor (3DSFET), or a complementary field effect transistor (CFET).

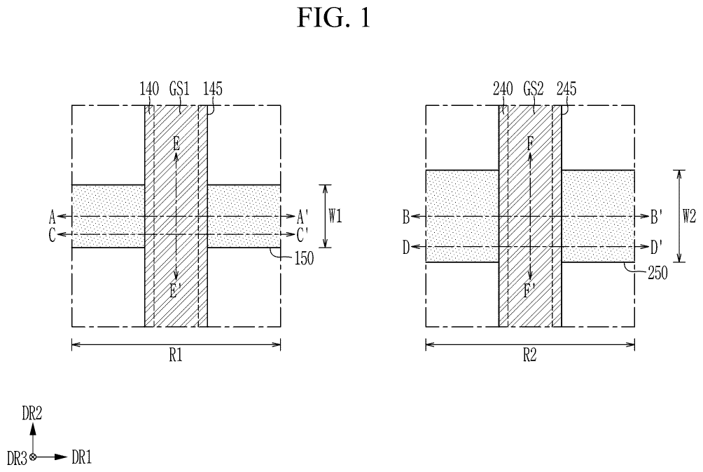

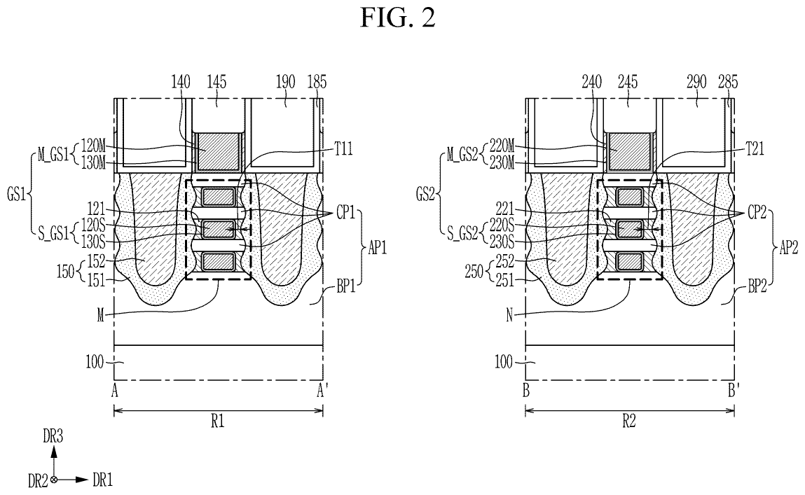

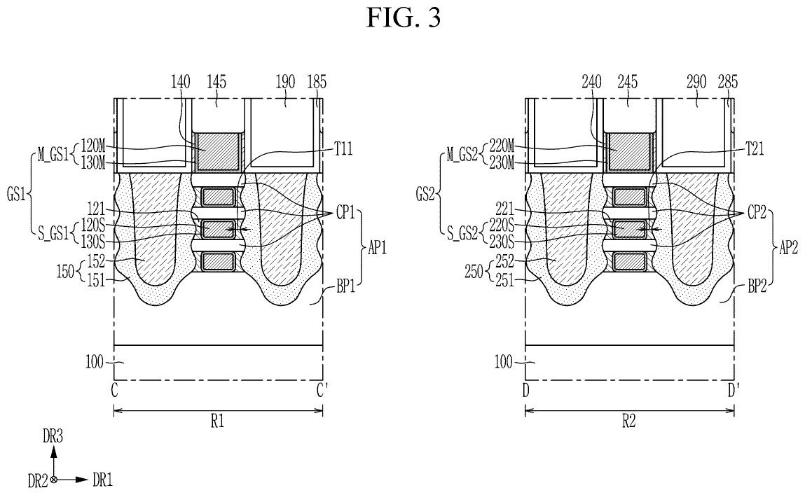

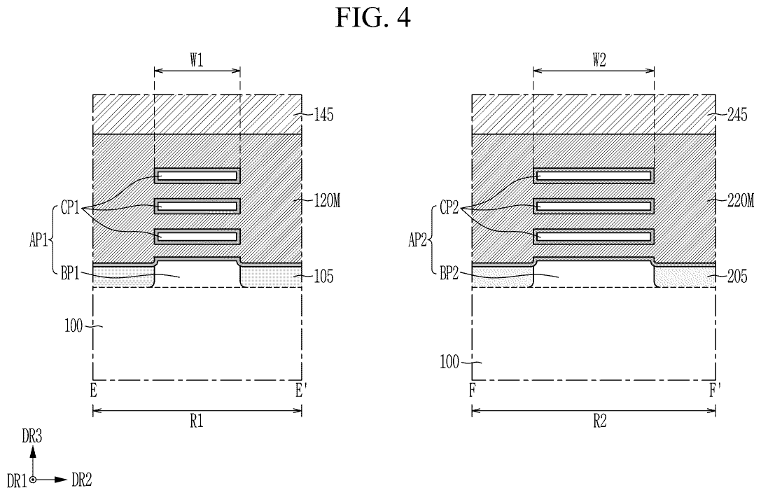

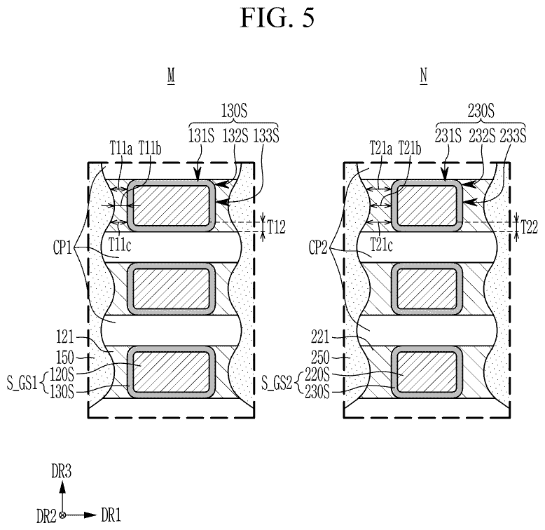

FIG. 1 is a top plan view showing a semiconductor device according to some embodiments. FIG. 2 is a cross-sectional view taken along lines A-A′ and B-B′ of FIG. 1. FIG. 3 is a cross-sectional view taken along lines C-C′ and D-D′ of FIG. 1. FIG. 4 is a cross-sectional view taken along lines E-E′ and F-F′ of FIG. 1. FIG. 5 is an enlarged view of a region M and a region N of FIG. 2.

Referring to FIGS. 1 to 5, a semiconductor device according to some embodiments may include a substrate 100 having a first region R1 and a second region R2. The first region R1 and the second region R2 may be regions spaced apart from each other, or may be regions connected to each other. In the first region R1 and the second region R2, transistors of different types may be formed, or transistors of the same type may be formed. Additionally, the first region R1 and the second region R2 may each be one of, for example, a logic region, a memory region (e.g., a static random-access memory (SRAM) region), or an input/output (I/O) region. In other words, the first region R1 and the second region R2 may be regions that perform the same function, or they may be regions that perform different functions.

In some embodiments, the first region R1 may be one of an SRAM region or a power input/output (I/O) region, and the second region R2 may be one of a logic region or a signal input/output (I/O) region, but the present disclosure is not limited thereto.

The semiconductor device according to some embodiments may include first and second source/drain patterns 150 and 250 positioned on each of the first region R1 and the second region R2 of the substrate 100, first and second channel patterns CP1 and CP2 positioned between the first and second source/drain patterns 150 and 250, and first and second gate structures GS1 and GS2 surrounding the first and second channel patterns CP1 and CP2. For example, the first source/drain patterns 150, the first channel patterns CP1, and the first gate structure GS1 may be on the first region R1 of the substrate 100, and the second source/drain patterns 250, the second channel patterns CP2, and the second gate structure GS2 may be on the second region R2 of the substrate 100. It will be understood that “an element A surrounds an element B” (or similar language) as used herein means that the element A is at least partially around the element B but does not necessarily mean that the element A completely encloses the element B.

According to some embodiments, the semiconductor device may further include first and second lower patterns BP1 and BP2 positioned on the first region R1 and the second region R2, respectively, of the substrate 100.

In other embodiments, the first and second lower patterns BP1 and BP2 may be omitted. The semiconductor device according to some embodiments may not have a lower insulating structure (not shown). In this case, the substrate 100 may be made of an insulation substrate including an insulating material, and the first and second lower patterns BP1 and BP2 may be made of an insulation pattern including an insulating material.

The semiconductor device according to some embodiments may further include first and second gate spacers 140 and 240, first and second capping layers 145 and 245, first and second etch stop layers 185 and 285, and first and second interlayer insulating layers 190 and 290 respectively positioned on the first region R1 and the second region R2 of the substrate 100.

According to some embodiments, the substrate 100 may be a silicon-on-insulator (SOI) or a bulk silicon. As another example, the substrate 100 may be a silicon substrate, or may include other materials, such as silicon germanium (SiGe), SGOI (silicon germanium on insulator), indium antimony, lead tellurium compound, indium arsenic, indium phosphide, gallium arsenic or antimonic gallium, but is not limited thereto.

The upper surface of the substrate 100 may be formed on a plane parallel to a first direction DR1 and a second direction DR2 that intersects the first direction DR1. In other words, the first direction DR1 and the second direction DR2 may intersect each other and may be parallel to the upper surface of the substrate 100.

According to some embodiments, the first and second activation patterns AP1 and AP2 may be positioned on the first region R1 and the second region R2 of the substrate 100, respectively. According to some embodiments, the first activation pattern AP1 may be positioned in a region where one of an NMOS or a PMOS is formed. According to some embodiments, the second activation pattern AP2 may be positioned in a region where one of an NMOS or a PMOS is formed.

According to some embodiments, the first and second activation patterns AP1 and AP2 may be extended longitudinally in the first direction DR1. According to some embodiments, the first and second activation patterns AP1 and AP2 may be multichannel activation patterns. The first and second activation patterns AP1 and AP2 may respectively include first and second lower patterns BP1 and BP2, and a plurality of first and second channel patterns CP1 and CP2.

According to some embodiments, the first and second lower patterns BP1 and BP2 and the plurality of first and second channel patterns CP1 and CP2 may have a nanosheet shape and may be a semiconductor pattern including a semiconductor material. The first and second lower patterns BP1 and BP2 may be positioned on (e.g., above) the substrate 100. The first and second lower patterns BP1 and BP2 may be extended longitudinally in the first direction DR1.

The first and second lower patterns BP1 and BP2 may be formed by etching a part of the substrate 100, or may include an epitaxial layer grown from the substrate 100. The first and second lower patterns BP1 and BP2 may include an elemental semiconductor material such as silicon (Si) or germanium (Ge). As another example, the first and second lower patterns BP1 and BP2 may include a compound semiconductor, for example, a Group IV-IV compound semiconductor or a Group III-V compound semiconductor.

The Group IV-IV compound semiconductors may be, for example, a binary compounds or a ternary compounds including at least two of carbon (C), silicon (Si), germanium (Ge), and tin (Sn).

The Group III-V compound semiconductors, for example, may be one of a binary compound, a ternary compound, or a quaternary compound formed by combining at least one of Group III elements aluminum (Al), gallium (Ga), and indium (In) and Group V elements phosphorus (P), arsenic (As), and antimony (Sb).

According to some embodiments, the first region R1 and the second region R2 of the substrate 100 have trenches defining the first and second lower patterns BP1 and BP2, respectively, and the first and second field insulating layers 105 and 205 may be positioned within each trench.

According to some embodiments, the first and second field insulating layers 105 and 205 may be positioned on the side walls of the first and second lower patterns BP1 and BP2, respectively. The first and second field insulating layers 105 and 205 may not be positioned on the upper surface of the first and second lower patterns BP1 and BP2, respectively. The first and second field insulating layers 105 and 205 may be on (e.g., may cover or overlap) the sides of the first and second lower patterns BP1 and BP2, respectively. In this case, the parts (i.e., portions) of the first and second lower patterns BP1 and BP2 may be protruded in the third direction DR3 rather than the upper surfaces of the first and second field insulating layers 105 and 205, respectively. At this time, the first and second field insulating layers 105 and 205 may be on (e.g., may cover) all or part of the side wall of the first and second lower patterns BP1 and BP2, respectively.

The first and second field insulating layers 105 and 205 may include insulating materials, for example oxide, nitride, oxynitride or combinations thereof. The first and second field insulating layers 105 and 205 are shown as a single layer, but this is only for better understanding and ease of description and the present disclosure is not limited thereto.

According to some embodiments, the plurality of first and second channel patterns CP1 and CP2 may be positioned on the upper surface of the first and second lower patterns BP1 and BP2, respectively. The plurality of first and second channel patterns CP1 and CP2 may be separated from the first and second lower patterns BP1 and BP2 in the third direction DR3, respectively. The plurality of first and second channel patterns CP1 and CP2 may be respectively separated in the third direction DR3. For example, the plurality of first channel patterns CP1 may be positioned apart from each other in the third direction DR3. The distance between the plurality of first channel patterns CP1 may all be the same, but is not limited thereto. Also, for example, the plurality of second channel patterns CP2 may be positioned apart from each other in the third direction DR3. The distance between the plurality of second channel patterns CP2 may all be the same, but is not limited thereto.

Here, the third direction DR3 may be a direction that intersects the first direction DR1 and the second direction DR2. For example, the third direction DR3 may be the thickness direction of the substrate 100. In other words, the third direction DR3 may be perpendicular to the upper surface of the substrate 100. The second direction DR2 may be a direction that intersects the first direction DR1. For example, the third direction DR3 may be a direction that vertically intersects the first direction DR1 and the second direction DR2.

Although not shown, the plurality of first channel patterns CP1 may be positioned spaced apart in the first direction DR1. Also, although not shown, the plurality of second channel patterns CP2 may be positioned spaced apart in the first direction DR1.

FIGS. 2 to 4 show that three first and second channel patterns CP1 and CP2 are stacked apart from each other along the third direction DR3, but this is for better understanding and ease of description and the present disclosure is not limited thereto. For example, four or more first and second channel patterns CP1 and CP2 may be stacked apart from each other along the third direction DR3.

According to some embodiments, the first channel pattern CP1 positioned on (e.g., above) the first region R1 may have a first width W1 along the second direction DR2. According to some embodiments, the second channel pattern CP2 positioned on (e.g., above) the second region R2 may have a second width W2 that is different from the first width W1 along the second direction DR2. For example, the second width W2 may be larger than the first width W1.

The plurality of first and second channel patterns CP1 and CP2 may include one of elemental semiconductor materials silicon (Si) or silicon germanium (SiGe), a Group IV-IV compound semiconductor, or a Group III-V compound semiconductor. Each of the plurality of first and second channel patterns CP1 and CP2 may include the same material as the first and second lower patterns BP1 and BP2, or may include material different from the first and second lower patterns BP1 and BP2.

As an example, the first and second lower patterns BP1 and BP2 and the plurality of first and second channel patterns CP1 and CP2 may include silicon (Si). As another example, the first and second lower patterns BP1 and BP2 and the plurality of first and second channel patterns CP1 and CP2 may include silicon germanium (SiGe). As another example, the first and second lower patterns BP1 and BP2 may include silicon (Si), and the plurality of first and second channel patterns CP1 and CP2 may include silicon germanium (SiGe).

According to some embodiments, the first and second gate structures GS1 and GS2 may be positioned on (e.g., above) the first and second lower patterns BP1 and BP2, respectively. The first and second gate structures GS1 and GS2 may intersect the first and second lower patterns BP1 and BP2. The first gate structure GS1 may surround each of the plurality of first channel patterns CP1. The second gate structure GS2 may surround each of the plurality of second channel patterns CP2. The first and second gate structures GS1 and GS2 may be extended in the second direction DR2. Although not shown, the plurality of first gate structures GS1 may be positioned spaced apart in the first direction DR1. Also, although not shown, the plurality of second gate structures GS2 may be positioned spaced apart in the first direction DR1.

According to some embodiments, the first gate structure GS1 may include a plurality of first sub-gate structures S_GS1 and a first main gate structure M_GS1. According to some embodiments, the second gate structure GS2 may include a plurality of second sub-gate structures S_GS2 and a second main gate structure M_GS2. The plurality of first and second sub-gate structures S_GS1 and S_GS2 may be located between the plurality of first and second channel patterns CP1 and CP2 adjacent to each other in the third direction DR3, and between the first and second lower patterns BP1 and BP2 and the first and second channel patterns CP1 and CP2 positioned at the lowest part. The first and second main gate structures M_GS1 and M_GS2 may be positioned on (e.g., above) the first and second channel patterns CP1 and CP2, respectively, which are positioned at the uppermost part.

In detail, the plurality of first sub-gate structures S_GS1 may be placed between the upper surface of the first lower pattern BP1 and the bottom surface of the lowermost first channel pattern CP1, and between the upper surface of the first channel pattern CP1 and the bottom surface of the first channel pattern CP1 facing in the third direction DR3. The plurality of second sub-gate structures S_GS2 may be placed between the upper surface of the second lower pattern BP2 and the bottom surface of the lowermost second channel pattern CP2, and between the upper surface of the second channel pattern CP2 and the bottom surface of the second channel pattern CP2 facing in the third direction DR3.

The plurality of first and second sub-gate structures S_GS1 and S_GS2 may be adjacent to the first and second source/drain patterns 150 and 250, respectively. In this case, other components (for example, first and second internal gate spacers 121 and 221) may be positioned between the plurality of first and second sub-gate structures S_GS1 and S_GS2 and the first and second source/drain patterns 150 and 250. The first and second main gate structures M_GS1 and M_GS2 may be positioned between the plurality of first and second sub-gate structures S_GS1 and S_GS2 and the first and second channel patterns CP1 and CP2, respectively.

According to some embodiments, the first and second activation patterns AP1 and AP2 may respectively include the plurality of first and second channel patterns CP1 and CP2, and the first and second gate structures GS1 and GS2 may respectively include the plurality of first and second sub-gate structures S_GS1 and S_GS2. At this time, the number of the plurality of first and second sub-gate structures S_GS1 and S_GS2 may be proportional to the number of the plurality of first and second channel patterns CP1 and CP2 included in first and second activation patterns AP1 and AP2. For example, the number of the plurality of first and second sub-gate structures S_GS1 and S_GS2 may be equal to the number of the plurality of first and second channel patterns CP1 and CP2, respectively. For example, as shown in FIG. 2, the number of the plurality of first and second sub-gate structures S_GS1 and S_GS2 may be three. However, the present disclosure is not limited thereto, and the plurality of first and second sub-gate structures S_GS1 and S_GS2 may include four or more first and second sub-gate structures S_GS1 and S_GS2, respectively.

Each of the plurality of first sub-gate structures S_GS1 may include a first sub-gate electrode 120S and a first sub-gate insulating layer 130S. Each of the plurality of second sub-gate structure S_GS2 may include a second sub-gate electrode 220S and a second sub-gate insulating layer 230S.

The first and second sub-gate electrodes 120S and 220S may be positioned on (e.g., above) the first and second lower patterns BP1 and BP2. The first and second sub-gate electrodes 120S and 220S and the first and second main gate electrodes 120M and 220M may surround the plurality of first and second channel patterns CP1 and CP2.

According to some embodiments, the sides of the first sub-gate structure S_GS1 and the first channel patterns CP1 may be covered by the first main gate structure M_GS1. According to some embodiments, the sides of the second sub-gate structure S_GS2 and the second channel patterns CP2 may be covered by the second main gate structure M_GS2.

According to some embodiments, at least a portion of the first sub-gate electrode 120S and the first main gate electrode 120M may be positioned on the stacking structure of the first sub-gate electrode 120S and the plurality of first channel patterns CP1. Another portion of the first sub-gate electrode 120S and the first main gate electrode 120M may be formed to be on (e.g., to cover) both sides of the stacking structure of the first sub-gate electrode 120S and the plurality of first channel patterns CP1. At this time, the four surfaces of the plurality of first channel patterns CP1 may be surrounded by the first sub-gate electrode 120S and the first main gate electrode 120M.

At least a portion of the second sub-gate electrode 220S and the second main gate electrode 220M may be positioned on the stacking structure of the second sub-gate electrode 220S and the plurality of second channel patterns CP2. Another portion of the second sub-gate electrode 220S and the second main gate electrode 220M may be formed to be on (e.g., to cover) both sides of the stacking structure of the second sub-gate electrode 220S and the plurality of second channel patterns CP2. At this time, four surfaces of the plurality of second channel patterns CP2 may be surrounded by the second sub-gate electrode 220S and the second main gate electrode 220M.

The first and second sub-gate electrodes 120S and 220S may include at least one of a metal, a metal alloy, a conductive metal nitride, a metal silicide, a doped semiconductor material, a conductive metal oxide, or a conductive metal oxynitride. The first and second sub-gate electrodes 120S and 220S, for example, may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but are not limited thereto. The conductive metal oxide and the conductive metal oxynitride may include oxidized forms of the above-mentioned materials, but are not limited thereto.

The first and second sub-gate insulating layers 130S, and 230S may surround the first and second sub-gate electrodes 120S and 220S, respectively. The first and second sub-gate insulating layers 130S and 230S may be positioned on (e.g., above) the first and second channel patterns CP1 and CP2, respectively. For example, the first and second sub-gate insulating layers 130S and 230S may be in directly contact with the first and second channel patterns CP1 and CP2, respectively. For example, the first and second sub-gate insulating layers 130S and 230S may include silicon oxide, silicon oxidation nitride or silicon nitride. Also, for example, the first and second sub-gate insulating layers 130S and 230S may include a high dielectric constant material. Also, for example, the first and second sub-gate insulating layers 130S and 230S may include both silicon oxide and a high dielectric constant material. High dielectric constant materials may include materials with a dielectric constant greater than silicon oxide (SiO₂), such as hafnium oxide (HfO), aluminum oxide (AlO), or tantalum oxide (TaO).

Referring to FIGS. 2 and 3, according to some embodiments, the first internal gate spacer 121 on the first region R1 may be positioned between the first source/drain pattern 150 and the first sub-gate structures S_GS1. According to some embodiments, the second internal gate spacer 221 on the second region R2 may be positioned between the second source/drain pattern 250 and the second sub-gate structure S_GS2.

Referring to FIGS. 2 and 3, according to some embodiments, the first thickness T11 and the second thickness T21 of the first and second internal gate spacers 121 and 221 may be respectively measured by being observed with a scanning electron microscope (SEM) or a scanning transmission electron microscope (STEM) on the cross-section of first and second channel patterns CP1 and CP2, respectively cut parallel to the first direction DR1 and third direction DR3.

In the present disclosure, the first thickness T11 and the second thickness T21 are not fixed values and may vary depending on the measurement region.

Referring to FIG. 2, according to some embodiments, the first thickness T11 and the second thickness T21 of each of the first and second internal gate spacers 121 and 221 may be measured by being observed with a scanning electron microscope (SEM) or a scanning electron microscope (STEM) at the midpoint along the second direction DR2 of the first and second channel patterns CP1 and CP2, respectively, on the cross-section cut parallel to the first direction DR1 and the third direction DR3.

According to some embodiments, the first internal gate spacer 121 may have the first thickness T11 along the first direction DR1 at the midpoint along the second direction DR2. In other words, the first thickness T11 of the first internal gate spacer 121 in FIG. 2 may be taken in the first direction DR1 at a center portion (e.g., a center point) of the first internal gate spacer 121 in the second direction DR2. For example, the line A-A′ may extend in the first direction DR1 and may intersect a center portion (e.g., a center point) of the first internal gate spacer 121 in the second direction DR2.

According to some embodiments, the second internal gate spacer 221 may have the second thickness T21 along the first direction DR1 at the midpoint along the second direction DR2. In other words, the second thickness T21 of the second internal gate spacer 221 in FIG. 2 may be taken in the first direction DR1 at a center portion (e.g., a center point) of the second internal gate spacer 221 in the second direction DR2. For example, the line B-B′ may extend in the first direction DR1 and may intersect a center portion (e.g., a center point) of the second internal gate spacer 221 in the second direction DR2.

According to some embodiments, the first thickness T11 and the second thickness T21 of the first and second internal gate spacers 121 and 221 may gradually decrease from the edges of both sides toward the middle point along the third direction DR3. In other words, the first thickness T11 and the second thickness T21 of the first and second internal gate spacers 121 and 221 may decrease from upper and lower surfaces of the first and second internal gate spacers 121 and 221 toward a center portion (e.g., a center point) of the first and second internal gate spacers 121 and 221 in the third direction DR3. That is, the first thickness T11 and the second thickness T21 of the first and second internal gate spacers 121 and 221 may decrease toward the third direction DR3 and then increase again. Accordingly, the first thickness T11 and the second thickness T21 of the first and second internal gate spacers 121 and 221 may be largest at both edges along the third direction DR3 and smallest at the midpoint along the third direction DR3.

According to some embodiments, two surfaces of the first internal gate spacer 121 facing each other along the first direction DR1 may have an approximately concave shape. Specifically, two faces facing each other of the first internal gate spacer 121 along the first direction DR1 may have an approximately concave shape on the cross-section along the first direction DR1 and the third direction DR3 perpendicular to the first direction DR1 and the second direction DR2. For example, the first internal gate spacer 121 may include a side surface that is opposite to the first gate structure GS1 in the first direction DR1 and has a concave shape, with the concave shape recessed inward toward the first gate structure GS1. The side surface of the first internal gate spacer 121 having the concave shape may face the first source/drain pattern 150. For example, the second internal gate spacer 221 may include a side surface that is opposite to the second gate structure GS2 in the first direction DR1 and has a concave shape, with the concave shape recessed inward toward the second gate structure GS2. The side surface of the second internal gate spacer 221 having the concave shape may face the second source/drain pattern 250.

Referring to FIG. 4, the first channel pattern CP1 may have a first width W1 along the second direction DR2, and the second channel pattern CP2 may have a second width W2 greater than the first width W1 along the second direction DR2. In this case, referring to FIG. 2, the second thickness T21 of the second internal gate spacer 221 at the midpoint along the second direction DR2 may be greater than the first thickness T11 of the first internal gate spacer 121 at the midpoint along the second direction DR2.

Referring to FIG. 3, according to some embodiments, the first thickness T11 and the second thickness T21 of the first and second internal gate spacers 121 and 221 may be measured by being observed with a scanning electron microscope (SEM) or a scanning transmission electron microscope (STEM) on the cross-section (i.e., FIG. 2 and FIG. 3) cut parallel to the first direction DR1 and the third direction DR3 at both end points along the second direction DR2 of the first and second channel patterns CP1 and CP2, respectively.

According to some embodiments, the first internal gate spacer 121 may have the first thickness T11 along the first direction DR1 at both end points along the second direction DR2. For example, the line C-C′ may extend in the first direction DR1 and may intersect an end portion (e.g., an edge) of the first internal gate spacer 121 in the second direction DR2.

According to some embodiments, the second internal gate spacer 221 may have the second thickness T21 along the first direction DR1 at both end points along the second direction DR2. For example, the line D-D′ may extend in the first direction DR1 and may intersect an end portion (e.g., an edge) of the second internal gate spacer 221 in the second direction DR2.

Referring to FIG. 4, the first channel pattern CP1 may have the first width W1 along the second direction DR2, and the second channel pattern CP2 may have the second width W2 greater than the first width W1 along the second direction DR2. In this case, referring to FIG. 3, the first thickness T11 at both end points of the first internal gate spacer 121 along the second direction DR2 may be similar to or identical to the second thickness T21 at both end points of the second internal gate spacer 221 along the second direction DR2.

Again, referring to FIGS. 2 to 4, when the first channel pattern CP1 has the first width W1 along the second direction DR2 and the second channel pattern CP2 has the second width W2 different from the first width W1 along the second direction DR2, the difference between the first thicknesses T11 at the edge and the midpoint of the first internal gate spacer 121 along the second direction DR2 may be different from the difference between the second thicknesses T21 at the edge and the midpoint of the second internal gate spacer 221 along the second direction DR2.

For example, if the second width W2 is about 1.5 to about 3 times greater than the first width W1 (e.g., see FIG. 4), the second thickness T21 at the midpoint of the second internal gate spacer 221 along the second direction DR2 may be about 1.1 to about 1.5 times greater than the first thickness T11 at the midpoint of the first internal gate spacer 121 along the second direction DR2 (e.g., see FIG. 2). In this case, the first thickness T11 at the edge of the first internal gate spacer 121 along the second direction DR2 may be similar to or identical to the second thickness T21 at the edge of the second internal gate spacer 221 along the second direction DR2 (e.g., see FIG. 3). Accordingly, the difference between the first thicknesses T11 of the edge and the midpoint of the first internal gate spacer 121 may be different from the difference between the second thicknesses T21 of the edge and the midpoint of the second internal gate spacer 221. Specifically, the difference between the first thicknesses T11 of the edge and the midpoint of the first internal gate spacer 121 may be less than the difference between the second thicknesses T21 of the edge and the midpoint of the second internal gate spacer 221. However, this is only an example and the present disclosure not limited thereto.

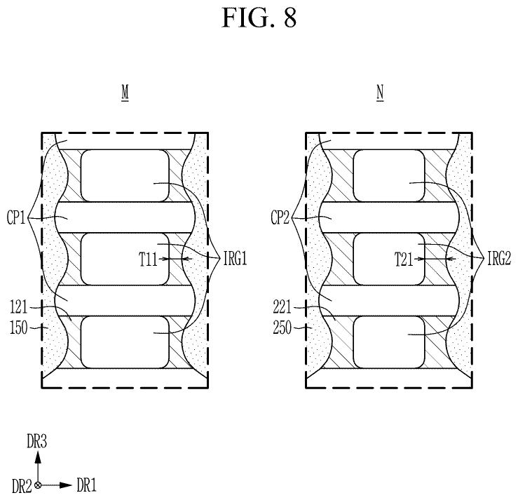

As the first channel pattern CP1 and the second channel pattern CP2 have the different widths along the second direction DR2, the specific details about the first internal gate spacer 121 and the second internal gate spacer 221 having the different thicknesses at the midpoint along the second direction DR2 are described later with reference to FIG. 8.

For example, the first and second internal gate spacers 121 and 221 may include silicon oxide (SiO₂).

According to some embodiments, the first and second main gate structures M_GS1 and M_GS2 may be positioned on (e.g., above) the first and second sub-gate structures S_GS1 and S_GS2 and the plurality of first and second channel patterns CP1 and CP2, respectively. The first and second main gate structures M_GS1 and M_GS2 may be positioned on the upper surface of the plurality of first and second channel patterns CP1 and CP2.

The first and second main gate structures M_GS1 and M_GS2 may include first and second main gate electrodes 120M and 220M, and first and second main gate insulating layers 130M and 230M, respectively.

The first and second main gate electrodes 120M and 220M may be positioned on the first and second sub-gate structures S_GS1 and S_GS2 and the plurality of first and second channel patterns CP1 and CP2, respectively. The first and second main gate electrodes 120M and 220M may be positioned on the upper surface of the plurality of first and second channel patterns CP1 and CP2. The first and second main gate electrodes 120M and 220M may be integrated with the first and second sub-gate electrodes 120S and 220S. The first and second main gate electrodes 120M and 220M may include the same material as the first and second sub-gate electrodes 120S and 220S. For example, the first and second main gate electrodes 120M and 220M may include at least one of a metal, a metal alloy, a conductive metal nitride, a metal silicide, a doped semiconductor material, a conductive metal oxide, or a conductive metal oxynitride.

The first and second main gate insulating layers 130M and 230M may extend along the side and bottom surfaces of the first and second main gate electrodes 120M and 220M. The first and second main gate insulating layers 130M and 230M may extend along the sides of the first and second gate spacers 140 and 240. For example, the first and second main gate insulating layers 130M and 230M may include silicon oxide, silicon oxidation nitride or silicon nitride. Also, for example, the first and second main gate insulating layers 130M and 230M may include a high dielectric constant material. Also, for example, the first and second main gate insulating layers 130M and 230M may include both silicon oxide and a high dielectric constant material.

The semiconductor device according to some embodiments may further include first and second gate spacers 140 and 240, and first and second capping layers 145 and 245 in the first region R1 and the second region R2, respectively.

According to some embodiments, the first and second gate spacers 140 and 240 may be positioned on both (i.e., opposing) sides of the first and second main gate electrodes 120M and 220M, respectively. The first and second gate spacers 140 and 240 may not be placed between the first and second lower patterns BP1 and BP2 and the plurality of first and second channel patterns CP1 and CP2, respectively. The first and second gate spacers 140 and 240 may not be placed between the plurality of first and second channel patterns CP1 and CP2 adjacent to each other in the third direction DR3.

According to some embodiments, the first and second gate spacers 140 and 240, for example, may include at least one of silicon nitride (SiN), silicon oxynitride (SiON), silicon oxide (SiO₂), silicon carbonate nitride (SiOCN), silicon boron nitride (SiBN), silicon oxyboron nitride (SiOBN), silicon oxycarbide (SiOC), or combinations thereof. The first and second gate spacers 140 and 240 are shown as a single layer, but this is only for better understanding and ease of description and the present disclosure is not limited thereto.

According to some embodiments, the first and second capping layers 145 and 245 may be positioned on (e.g., above) the first and second main gate structures M_GS1 and M_GS2, respectively. The first and second capping layers 145 and 245 may be positioned on (e.g., above) the first and second main gate structures M_GS1 and M_GS2 and the first and second gate spacers 140 and 240. The upper surfaces of the first and second capping layers 145 and 245 may lie on the same plane as (i.e., may be coplanar with) the upper surfaces of the first and second interlayer insulating layers 190 and 290, respectively.

The first and second capping layers 145 and 245, for example, may include silicon nitride (SiN), silicon oxynitride (SiON), silicon (Si) carbonization nitride (SiCN), silicon carbonate nitride (SiOCN), and combinations thereof. The first and second capping layers 145 and 245 may include a material with an etch selectivity against the first and second interlayer insulating layers 190 and 290.

The first and second source/drain patterns 150 and 250 may be positioned on (e.g., above) the first and second lower patterns BP1 and BP2, respectively.

The first and second source/drain patterns 150 and 250 may be positioned between the first and second sub-gate structures S_GS1 and S_GS2 adjacent in the first direction DR1. For example, the first and second source/drain patterns 150 and 250 may be positioned on both (i.e., opposing) sides of the first and second sub-gate structures S_GS1 and S_GS2.

The first and second source/drain patterns 150 and 250 may be positioned on the sides of the first and second channel patterns CP1 and CP2, respectively. For example, the first and second source/drain patterns 150 and 250 may be in contact with the sides of the first and second channel patterns CP1 and CP2, respectively. The first and second source/drain patterns 150 and 250 may be positioned between the first and second channel patterns CP1 and CP2 adjacent to each other in the first direction DR1.

According to some embodiments, the first and second source/drain patterns 150 and 250 may be in contact with the sides of the first and second internal gate spacers 121 and 221, respectively.

The sides of the first and second source/drain patterns 150 and 250 may have a bumpy embossing shape. In other words, the sides of the first and second source/drain patterns 150 and 250 may have a wavy profile. For example, the sides of the first and second source/drain patterns 150 and 250 adjacent to the first and second internal gate spacers 121 and 221 may have a roughly convex shape toward the first and second internal gate spacers 121 and 221, and the sides of the first and second source/drain patterns 150 and 250 adjacent to the first and second channel patterns CP1 and CP2 may have a roughly concave shape toward the first and second channel patterns CP1 and CP2.

According to some embodiments, the first and second source/drain patterns 150 and 250 may be epitaxial patterns formed by a selective epitaxial growth process using the first and second activation patterns AP1 and AP2 as seeds, respectively. The first and second source/drain patterns 150 and 250 may include at least one of silicon (Si) or silicon germanium (SiGe), according to some embodiments. The first and second channel patterns CP1 and CP2 may be parts of the first and second activation patterns AP1 and AP2 extending between the first and second source/drain patterns 150 and 250. The first and second source/drain patterns 150 and 250 may serve as the source/drain of the transistor that uses the first and second channel patterns CP1 and CP2 as a channel region.

The first and second source/drain patterns 150 and 250 may include first and second lower source/drain layers 151 and 251 and first and second upper source/drain layers 152 and 252, respectively. The first and second lower source/drain layers 151 and 251 may have a shape surrounding the side and bottom surfaces of the first and second upper source/drain layers 152 and 252, respectively.

The first and second channel patterns CP1 and CP2 may be in contact with the first and second lower source/drain layers 151 and 251, respectively, and may not be in contact with the first and second upper source/drain layers 152 and 252. Therefore, the first and second lower source/drain layers 151 and 251 may be positioned between the first and second channel patterns CP1 and CP2 and the first and second upper source/drain layers 152 and 252.

However, the present disclosure is not limited thereto, and at least some of the first and second channel patterns CP1 and CP2 may be in contact with the first and second upper source/drain layers 152 and 252, according to some embodiments. Additionally, the first and second source/drain patterns 150 and 250 may not be divided into the first and second lower source/drain layers 151 and 251 and the first and second upper source/drain layers 152 and 252, but may be formed as a single layer, according to some embodiments.

The first and second source/drain patterns 150 and 250 may include SiGe. The Ge content of the first and second lower source/drain layers 151 and 251 may be different from the Ge content of the first and second upper source/drain layers 152 and 252.

The first and second lower source/drain layers 151 and 251 may be made of SiGe including low concentration Ge, and the first and second upper source/drain layers 152 and 252 may be made of SiGe including high concentration Ge. However, the material of the first and second source/drain patterns 150 and 250 is not limited thereto and may be changed in various ways.

According to some embodiments, the bottom surface of the first and second source/drain patterns 150 and 250 may be positioned at a lower level than the bottom surface of the plurality of first and second sub-gate structures S_GS1 and S_GS2. For example, as shown in FIGS. 2 and 3, the lower surface of the first and second source/drain patterns 150 and 250 may be positioned closer to the lower surface of the first and second lower patterns BP1 and BP2 than the lower surface of the first and second sub-gate structures S_GS1 and S_GS2, which are positioned at the lowermost part.

According to some embodiments, the first and second etch stop layers 185 and 285 may be positioned on the sides of the first and second gate spacers 140 and 240 and on the upper surface of the first and second source/drain patterns 150 and 250, respectively.

The first and second etch stop layers 185 and 285 may include a material with an etch selectivity against first and second interlayer insulating layers 190 and 290, which will be described later. The first and second etch stop layers 185 and 285, for example, may include silicon nitride (SiN), silicon oxynitride (SiON), silicon carbonate nitride (SiOCN), silicon boron nitride (SiBN), silicon oxyboron nitride (SiOBN), silicon oxycarbide (SiOC), or combinations thereof.

The first and second interlayer insulating layers 190 and 290 may be positioned on (e.g., above) the first and second etch stop layers 185 and 285, respectively. The first and second interlayer insulating layers 190 and 290 may be positioned on (e.g., above) the first and second source/drain patterns 150 and 250. The first and second interlayer insulating layers 190 and 290 may not be on (e.g., may not cover) the upper surface of the first and second capping layers 145 and 245.

The first and second interlayer insulating layers 190 and 290 may include at least one of, for example, silicon oxide (SiO₂), silicon nitride (SiN), silicon oxynitride (SiON), or a low dielectric constant material. The low dielectric constant material, for example, may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride silicate glass), polyimide nanofoams such as polypropylene oxide, CDO (Carbon Doped silicon Oxide), OSG (Organo silicate glass), SiLK, Amorphous Fluorinated Carbon, silica aerogels, silica xerogels, mesoporous silica, or a combination thereof, but is not limited thereto.

Referring to FIG. 5, each of the first and second sub-gate insulating layers 130S and 230S may include first and second horizontal parts 131S and 231S on the first and second channel patterns CP1 and CP2, first and second vertical parts 133S and 233S on the first and second internal gate spacers 121 and 221, and first and second corner parts 132S and 232S between the first and second horizontal parts 131S and 231S and the first and second vertical parts 133S and 233S. Here, the first and second vertical parts 133S and 233S may face the convex side of the first and second source/drain patterns 150 and 250 in the first direction DR1.

According to some embodiments, the first and second horizontal parts 131S and 231S, the first and second vertical parts 133S and 233S, and the first and second corner parts 132S and 232S between the first and second horizontal parts 131S and 231S and the first and second vertical parts 133S and 233S may be formed integrally connected.

According to some embodiments, the thicknesses of the first and second internal gate spacers 121 and 221 corresponding to the length along the third direction DR3 from the point where the first and second vertical parts 133S and 233S and the first and second corner parts 132S and 232S are connected (i.e., are in contact) to the surface where the first and second internal gate spacers 121 and 221 are in contact with the first and second channel patterns CP1 and CP2 may be a third thickness T12 and a fourth thickness T22, respectively.

According to some embodiments, the third thickness T12 may be less than half (½) of the first average thickness, which is the average value of the thickness at the edge and the center of the first internal gate spacer 121 along the third direction DR3. Specifically, the third thickness T12 may be less than half (½) of the first average thickness, which is the average value of the first upper thickness T11a, the first central portion thickness T11b, and the first lower thickness T11c of the first internal gate spacer 121. More specifically, the third thickness T12 may be less than one-third (⅓) times of the first average thickness.

Here, the first upper thickness T11a may correspond to the thickness along the first direction DR1 at the upper part (i.e., upper portion) of the first internal gate spacer 121. Specifically, the first upper thickness T11a may correspond to the thickness of the first internal gate spacer 121 along the first direction DR1 at the point where the upper part of the first vertical part 133S and the first corner part 132S are connected. The first central portion thickness T11b may correspond to the thickness along the first direction DR1 at the midpoint of the first internal gate spacer 121 along the third direction DR3. The first lower thickness T11c may correspond to the thickness along the first direction DR1 at the lower part (i.e., lower portion) of the first internal gate spacer 121. Specifically, the first lower thickness T11c may correspond to the thickness of the first internal gate spacer 121 along the first direction DR1 at the point where the lower part of the first vertical part 133S and the first corner part 132S are connected.

According to some embodiments, the fourth thickness T22 may be less than or equal to half (½) of a second average thickness, which is an average value of the thickness at the edge and the center of the second internal gate spacer 221 along the third direction DR3. Specifically, the fourth thickness T22 may be less than half (½) of the second average thickness, which is the average value of the second upper thickness T21a, the second central portion thickness T21b, and the second lower thickness T21c of the second internal gate spacer 221. More specifically, the fourth thickness T22 may be less than one-third (⅓) times of the second average thickness.

Here, the second upper thickness T21a may correspond to the thickness along the first direction DR1 at the upper part (i.e., upper portion) of the second internal gate spacer 221. Specifically, the second upper thickness T21a may correspond to the thickness of the second internal gate spacer 221 along the first direction DR1 at the point where the upper part of the second vertical part 233S and the second corner part 232S are connected. The second central portion thickness T21b may correspond to the thickness along the first direction DR1 at the midpoint along the third direction DR3 of the second internal gate spacer 221. The second lower thickness T21c may correspond to the thickness along the first direction DR1 at the lower part (i.e., lower portion) of the second internal gate spacer 221. Specifically, the second lower thickness T21c may correspond to the thickness of the second internal gate spacer 221 along the first direction DR1 at the point where the lower part of the second vertical part 233S and the second corner part 232S are connected.

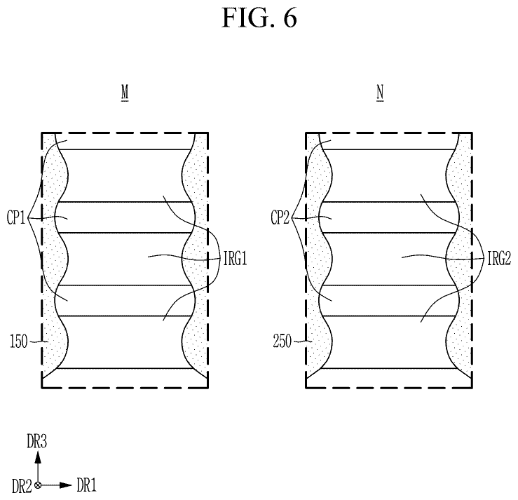

FIGS. 6 to 10 are enlarged views to explain a method of forming a region M and a region N of FIG. 2 according to some embodiments. In other words, FIGS. 6 to 10 are enlarged views to explain a method of forming the region M and the region N of FIG. 2 on the cross-section (i.e., FIG. 2) cut parallel to the first direction DR1 and the third direction DR3 at the midpoint (the ½ point) of first and second channel patterns CP1 and CP2 according to the second direction DR2.

Although not shown, a structure may be formed by alternately stacking a sacrificial layer and a semiconductor material layer on the first region R1 and the second region R2, respectively, and then patterning them to form first and second source/drain recesses (not shown). After forming first and second source/drain patterns 150 and 250 within the first and second source/drain recesses (not shown), the sacrificial layer may be removed to form first and second internal spaces IRG1 and IRG2.

According to some embodiments, the sacrificial layer is made of a material with high selectivity against the first and second channel patterns CP1 and CP2 and the first and second source/drain patterns 150 and 250. For example, the sacrificial layer may be made of SiGe, the first and second channel patterns CP1 and CP2 may be made of Si, and the first and second source/drain patterns 150 and 250 may be made of SiGe. At this time, the etching process may be performed using an etching solution that has a relatively high etch rate against silicon oxide. Therefore, the sacrificial layer is removed, and the first and second channel patterns CP1 and CP2 and the first and second source/drain patterns 150 and 250 remain. Accordingly, as shown in FIG. 6, the first and second internal spaces IRG1 and IRG2 may be formed in the area where the sacrificial layer is removed.

As the first and second internal spaces IRG1 and IRG2 are formed, at least some of the sides of the first and second source/drain patterns 150 and 250 may be exposed. Additionally, the upper and/or lower surfaces of the first and second channel patterns CP1 and CP2 may be exposed by the first and second internal spaces IRG1 and IRG2.

Accordingly, the first and second internal spaces IRG1 and IRG2 may be surrounded by the first and second channel patterns CP1 and CP2 and the first and second source/drain patterns 150 and 250. Referring back to FIG. 4, as described above, the first channel patterns CP1 may be connected between the first source/drain patterns 150, and may have the first width W1 in the second direction DR2. For example, the first channel patterns CP1 may electrically connect the first source/drain patterns 150 to each other. Also, still referring to FIG. 4, as described above, the second channel patterns CP2 may be connected between the second source/drain patterns 250, and may have the second width W2 that is different from the first width W1 in the second direction DR2. For example, the second channel patterns CP2 may electrically connect the second source/drain patterns 250 to each other.

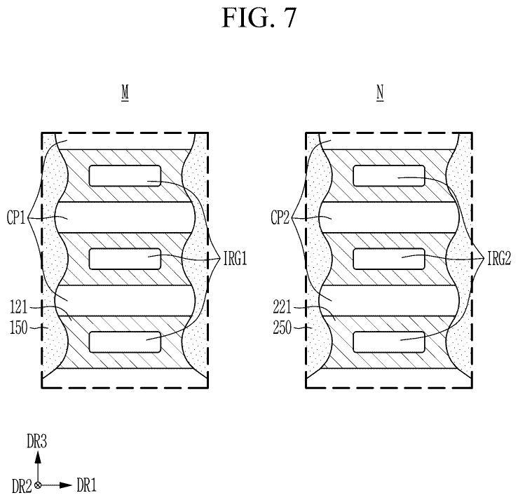

Referring to FIG. 7, according to some embodiments, first and second internal gate spacers 121 and 221 may be formed within the first and second internal spaces IRG1 and IRG2.

The first and second internal gate spacers 121 and 221 may be formed by using an atomic layer deposition (ALD) process, a chemical vapor deposition (CVD) process, and/or a physical vapor deposition (PVD) process, but are not limited thereto. According to some embodiments, the deposition of first and second internal gate spacers 121 and 221 may be performed in the same process, but the present disclosure is not limited thereto.

According to some embodiments, the first and second internal gate spacers 121 and 221 may be conformally formed within first and second internal spaces IRG1 and IRG2, respectively. In other words, the first and second internal gate spacers 121 and 221 may be formed on the exposed surface of the first and second channel patterns CP1 and CP2 and the exposed surface of the first and second source/drain patterns 150 and 250, respectively.

According to some embodiments, the first and second internal gate spacers 121 and 221 may be formed to partially fill the first and second internal spaces IRG1 and IRG2, respectively, rather than completely filling them.

According to some embodiments, the first and second internal gate spacers 121 and 221 may have a roughly convex or flat shape toward the first and second internal spaces IRG1 and IRG2 with the surface in contact with the first and second internal spaces IRG1 and IRG2, and the first and second internal gate spacers 121 and 221 may have a roughly concave or flat shape toward the first and second source/drain patterns 150 and 250 with the surface in contact with the first and second source/drain patterns 150 and 250.

The first and second internal gate spacers 121 and 221 may include a low dielectric constant material. The low dielectric constant material may include silicon oxide or a material with a dielectric constant lower than silicon oxide. For example, the low dielectric constant material may include silicon oxide, silicon oxide doped with fluorine or carbon, porous silicon oxide, organic polymeric dielectric, or a combination thereof.

Referring to FIG. 8, according to some embodiments, the first and second internal gate spacers 121 and 221 may be removed (e.g., may be partially removed) through an etching process. According to some embodiments, the etching of the first and second internal gate spacers 121 and 221 may be performed in the same process, but the present disclosure is not limited thereto.

According to some embodiments, etching the first and second internal gate spacers 121 and 221 may include a wet etching process using an etching solution that selectively etches only the first and second internal gate spacers 121 and 221. Specifically, an etching material may be provided through the first and second internal spaces IRG1 and IRG2 to enable the etching of the first and second internal gate spacers 121 and 221.

More specifically, the etching material is provided through the entrances of both edges of the first and second internal spaces IRG1 and IRG2 along the second direction DR2, so that the first and second internal gate spacers 121 and 221 may be etched. Accordingly, the first thickness T11 of the first internal gate spacer 121 and/or the second thickness T21 of the second internal gate spacer 221 may gradually increase from both edges toward the middle point along the second direction DR2. In other words, the first thickness T11 of the first internal gate spacer 121 and/or the second thickness T21 of the second internal gate spacer 221 may increase along the second direction DR2 and then decrease again.

According to some embodiments, still referring to FIG. 8 and referring back to FIG. 4, as described above, when the first channel pattern CP1 has the first width W1 along the second direction DR2, and the second channel pattern CP2 has the second width W2 greater than the first width W1 along the second direction DR2, the second thickness T21 at the edge of the second internal gate spacer 221 along the second direction DR2 may be similar to or identical to the first thickness T11 at the edge of the first internal gate spacer 121 along the second direction DR2 (e.g., see FIG. 3). Specifically, as the etching material is provided through the first and second internal spaces IRG1 and IRG2 from both ends of the second direction DR2, the second thickness T21 at the edge of the second internal gate spacer 221 along the second direction DR2 may be similar to or identical to the first thickness T11 at the edge of the first internal gate spacer 121 along the second direction DR2 (e.g., see FIG. 3).

According to some embodiments, when the first channel pattern CP1 has the first width W1 along the second direction DR2, and the second channel pattern CP2 has the second width W2 that is different from the first width W1 along the second direction DR2, the etching amount (or the remaining amount) of the first and second internal gate spacers 121 and 221 at the midpoint of the first and second channel patterns CP1 and CP2 along the second direction DR2 may be different (e.g., see FIGS. 2 and 8).

For example, if the first channel pattern CP1 has the first width W1 along the second direction DR2, and the second channel pattern CP2 has the second width W2 greater than the first width W1 along the second direction DR2, the etching amount of the second internal gate spacer 221, which is positioned on (e.g., above) the midpoint of the first and second channel patterns CP1 and CP2 along the second direction DR2, may be less than the etching amount of the first internal gate spacer 121 during the same time. Accordingly, the remaining amount of the second internal gate spacer 221 may be larger than the remaining amount of the first internal gate spacer 121 at the midpoint along the second direction DR2 (e.g., see FIGS. 2 and 8).

Accordingly, as shown in FIG. 8, the second thickness T21 at the midpoint of the second internal gate spacer 221 along the second direction DR2 may be greater than the first thickness T11 at the midpoint of the first internal gate spacer 121 along the second direction DR2.

According to some embodiments, the etching process may be performed until the surfaces of first and second channel patterns CP1 and CP2 are exposed. According to some embodiments, after the etching process, the first and second internal gate spacers 121 and 221 may remain on the surface of the first and second source/drain patterns 150 and 250, respectively. The remaining first and second internal gate spacers 121 and 221, compared with FIG. 7, may provide the expanded first and second internal spaces IRG1 and IRG2.

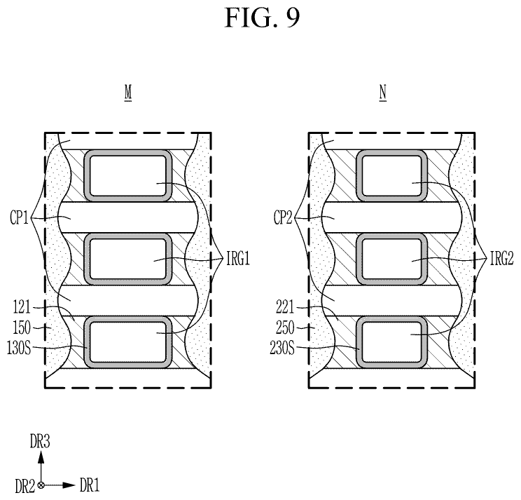

Referring to FIG. 9, according to some embodiments, the first and second sub-gate insulating layers 130S and 230S may be formed within the first and second internal spaces IRG1 and IRG2.

According to some embodiments, the first and second sub-gate insulating layers 130S and 230S may be formed using an atomic layer deposition (ALD) process, a chemical vapor deposition (CVD) process, and/or a physical vapor deposition (PVD) process, but are not limited thereto.

According to some embodiments, the first and second sub-gate insulating layers 130S and 230S may be conformally formed within the first and second internal spaces IRG1 and IRG2, respectively. In other words, the first and second sub-gate insulating layers 130S and 230S may each have a uniform thickness. According to some embodiments, the first and second sub-gate insulating layers 130S and 230S may be formed on the first and second internal gate spacers 121 and 221, respectively.

Additionally, according to some embodiments, the first and second sub-gate insulating layers 130S and 230S may be formed on the first and second channel patterns CP1 and CP2, respectively. Specifically, the first and second sub-gate insulating layers 130S and 230S may be formed on the first and second internal gate spacers 121 and 221 along the first direction DR1, respectively, and on the first and second channel patterns CP1 and CP2 along the third direction DR3.

For example, the first and second sub-gate insulating layers 130S and 230S may include silicon oxide, silicon oxidation nitride or silicon nitride. Also, for example, the first and second sub-gate insulating layers 130S and 230S may include a high dielectric constant material. Also, for example, the first and second sub-gate insulating layers 130S and 230S may include both silicon oxide and a high dielectric constant material. The high dielectric constant materials may include materials with a dielectric constant greater than silicon oxide (SiO₂), such as hafnium oxide (HfO), aluminum oxide (AlO), or tantalum oxide (TaO).

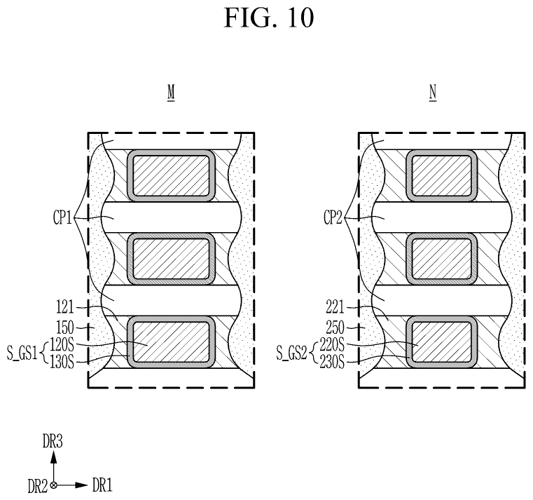

Referring to FIG. 10, first and second sub-gate electrodes 120S and 220S may be formed on the first and second sub-gate insulating layers 130S and 230S according to some embodiments.

According to some embodiments, the first and second sub-gate electrodes 120S and 220S may be formed to be in (e.g., to fill) the first and second internal spaces IRG1 and IRG2.

The first and second sub-gate electrodes 120S and 220S may be formed using an atomic layer deposition (ALD) process, a chemical vapor deposition (CVD) process, etc. The first and second sub-gate electrodes 120S and 220S may include a doped polysilicon, a metal, a conductive metal nitride, a conductive metal carbide, or combinations thereof. However, this is only an example, and the material of the first and second sub-gate electrodes 120S and 220S is not limited thereto.

As described above, in the semiconductor device according to some embodiments of the present disclosure, by varying the thickness of the first and second internal gate spacers 121 and 221 according to the width of the first and second channel patterns CP1 and CP2 on (e.g., above) the first region R1 and the second region R2, respectively, the reliability according to the characteristics of each region may be secured.

For example, in the semiconductor device according to some embodiments of the present disclosure, by varying the thickness of the first and second internal gate spacers 121 and 221 depending on whether the AC characteristic is an important element region or the DC characteristic is an important element region, the reliability according to the characteristic of each region may be secured.

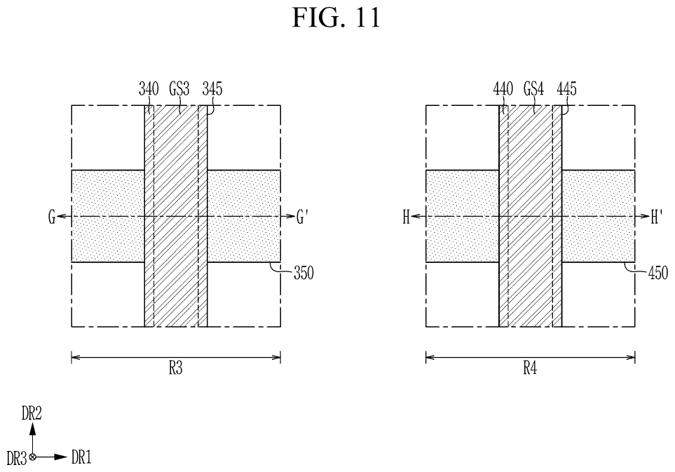

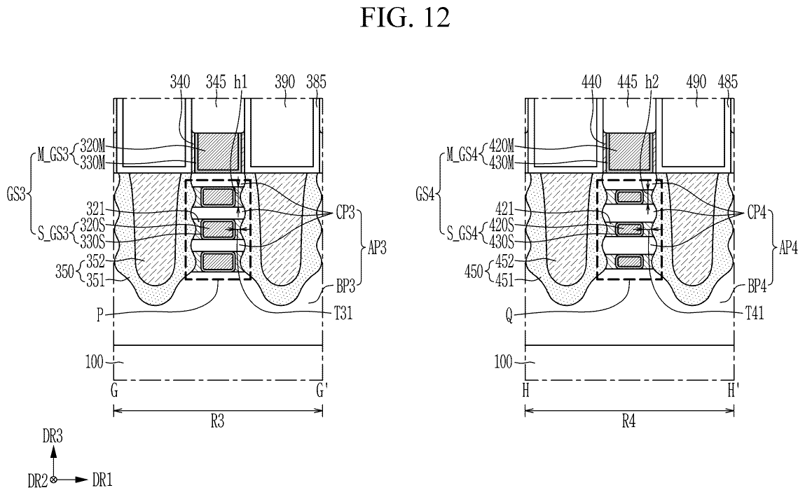

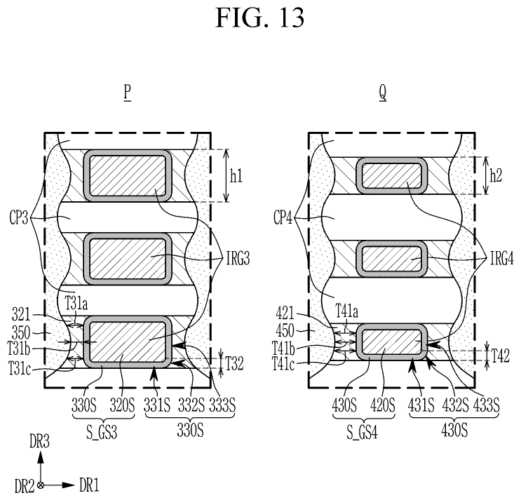

FIG. 11 is a top plan view showing a semiconductor device according to some further embodiments. FIG. 12 is a cross-sectional view taken along lines G-G′ and H-H′ of FIG. 11. FIG. 13 is an enlarged view of a region P and a region Q of FIG. 12. Details regarding the formation process and materials of the components shown in FIGS. 11 to 13 may be the same or similar to that described above with reference to FIGS. 1 to 10.

Referring to FIGS. 11 to 13, a semiconductor device according to some further embodiments may include a substrate 100 having a first region R3 and a second region R4. The first region R3 and the second region R4 may be regions spaced apart from each other, or may be regions connected to each other. In the first region R3 and the second region R4, transistors of different types may be formed, or transistors of the same type may be formed. Additionally, the first region R3 and the second region R4 may each be one of, for example, a logic region, a memory region (e.g., an SRAM region), or an input/output (I/O) region. In other words, the first region R3 and the second region R4 may be regions that perform the same function, or may be regions that perform different functions.

In some embodiments, the first region R3 may be one of an SRAM region or a power input/output (I/O) region, and the second region R4 may be one of a logic region or a signal input/output (I/O) region, but the present disclosure is not limited thereto.

The semiconductor device according to some embodiments may include first and second source/drain patterns 350 and 450 respectively positioned on the first region R3 and the second region R4 of the substrate 100, first and second channel patterns CP3 and CP4 positioned between the first and second source/drain patterns 350 and 450, and first and second gate structures GS3 and GS4 surrounding the first and second channel patterns CP3 and CP4. For example, the first source/drain patterns 350, the first channel patterns CP3, and the first gate structure GS3 may be on the first region R3 of the substrate 100, and the second source/drain patterns 450, the second channel patterns CP4, and the second gate structure GS4 may be on the second region R4 of the substrate 100.

According to some embodiments, the semiconductor device may further include first and second lower patterns BP3 and BP4 positioned on (e.g., above) the first region R3 and the second region R4, respectively, of the substrate 100.

In other embodiments, the first and second lower patterns BP3 and BP4 may be omitted. The semiconductor device according to some embodiments may not have a lower insulating structure (not shown). In this case, the substrate 100 may be made of an insulation substrate including an insulating material, and the first and second lower patterns BP3 and BP4 may be made of an insulation pattern including an insulating material.

According to some embodiments, the semiconductor device may further include first and second gate spacers 340 and 440, first and second capping layers 345 and 445, first and second etch stop layers 385 and 485, and first and second interlayer insulating layers 390 and 490 respectively positioned on the first region R3 and the second region R4 of the substrate 100.

According to some embodiments, the substrate 100 may be a silicon-on-insulator (SOI) or a bulk silicon. As another example, the substrate 100 may be a silicon substrate, or may include other materials, such as silicon germanium (SiGe), SGOI (silicon germanium on insulator), indium antimony, lead tellurium compound, indium arsenic, indium phosphide, gallium arsenic or antimonic gallium, but is not limited thereto.

The upper surface of the substrate 100 may be formed on a plane parallel to a first direction DR1 and a second direction DR2 that intersects the first direction DR1.

According to some embodiments, the first and second activation patterns AP3 and AP4 may be positioned on the first region R3 and the second region R4 of the substrate 100, respectively. According to some embodiments, the first activation pattern AP3 may be positioned in a region where one of an NMOS or a PMOS is formed. According to some embodiments, the second activation pattern AP4 may be positioned in a region where one of an NMOS or a PMOS is formed.

According to some embodiments, the first and second activation patterns AP3 and AP4 may be extended longitudinally in the first direction DR1. According to some embodiments, the first and second activation patterns AP3 and AP4 may be multi-channel activation patterns. The first and second activation patterns AP3 and AP4 may respectively include first and second lower patterns BP3 and BP4 and a plurality of first and second channel patterns CP3 and CP4.

According to some embodiments, the first and second lower patterns BP3 and BP4 and the plurality of first and second channel patterns CP3 and CP4 may have a nanosheet shape and may be a semiconductor pattern including a semiconductor material. The first and second lower patterns BP3 and BP4 may be positioned on the substrate 100. The first and second lower patterns BP3 and BP4 may be extended longitudinally in the first direction DR1.

The first and second lower patterns BP3 and BP4 may be formed by etching a portion of the substrate 100, or may include an epitaxial layer grown from the substrate 100. The first and second lower patterns BP3 and BP4 may include an elemental semiconductor material such as silicon (Si) or germanium (Ge). As another example, the first and second lower patterns BP3 and BP4 may include a compound semiconductor, for example, a Group IV-IV compound semiconductor or a Group III-V compound semiconductor.

The Group IV-IV compound semiconductors may be, for example, a binary compounds or a ternary compounds including at least two of carbon (C), silicon (Si), germanium (Ge), and tin (Sn).

The Group III-V compound semiconductors, for example, may be one of a binary compound, a ternary compound, or a quaternary compound formed by combining at least one of Group III elements aluminum (Al), gallium (Ga), and indium (In) and Group V elements phosphorus (P), arsenic (As), and antimony (Sb).

According to some embodiments, the plurality of first and second channel patterns CP3 and CP4 may be positioned on the upper surface of the first and second lower patterns BP3 and BP4, respectively. The plurality of first and second channel patterns CP3 and CP4 may be separated from the first and second lower patterns BP3 and BP4 in the third direction DR3, respectively. The plurality of first and second channel patterns CP3 and CP4 may be respectively separated in the third direction DR3. For example, the plurality of first channel patterns CP3 may be positioned apart from each other in the third direction DR3. The distance between the plurality of first channel patterns CP3 may all be the same, but the present disclosure is not limited thereto. Also, for example, the plurality of second channel patterns CP4 may be positioned spaced apart in the third direction DR3. The distance between the plurality of second channel patterns CP4 may all be the same, but the present disclosure is not limited thereto.

According to some embodiments, the distance between the first channel patterns CP3 and the distance between the second channel patterns CP4 may be different. For example, the distance between the first channel patterns CP3 may be greater than the distance between the second channel patterns CP4.

Here, the third direction DR3 may be a direction that intersects the first direction DR1 and the second direction DR2. For example, the third direction DR3 may be the thickness direction of the substrate 100. The second direction DR2 may be a direction that intersects the first direction DR1. For example, the third direction DR3 may be a direction that vertically intersects the first direction DR1 and the second direction DR2.

Although not shown, the plurality of first channel patterns CP3 may be positioned spaced apart in the first direction DR1. Also, although not shown, the plurality of second channel patterns CP4 may be positioned spaced apart in the first direction DR1.

FIG. 12 shows that three first and second channel patterns CP3 and CP3 are stacked apart from each other along the third direction DR3, but this is for better understanding and ease of description and the present disclosure is not limited thereto. For example, four or more first and second channel patterns CP3 and CP4 may be stacked apart from each other along the third direction DR3.

The plurality of first and second channel patterns CP3 and CP4 may include one of elemental semiconductor materials silicon (Si) or silicon germanium (SiGe), a Group IV-IV compound semiconductor, or a Group III-V compound semiconductor. Each of the plurality of first and second channel patterns CP3 and CP4 may include the same material as the first and second lower patterns BP3 and BP4, or may include a material different from the first and second lower patterns BP3 and BP4.

As an example, the first and second lower patterns BP3 and BP4 and the plurality of first and second channel patterns CP3 and CP4 may include silicon (Si). As another example, the first and second lower patterns BP3 and BP4 and the plurality of first and second channel patterns CP3 and CP4 may include silicon germanium (SiGe). As another example, the first and second lower patterns BP3 and BP4 may include silicon (Si), and the plurality of first and second channel patterns CP3 and CP4 may include silicon germanium (SiGe).

According to some embodiments, the first and second gate structures GS3 and GS4 may be positioned on (e.g., above) the first and second lower patterns BP3 and BP4, respectively. The first and second gate structures GS3 and GS4 may intersect the first and second lower patterns BP3 and BP4. The first gate structure GS3 may surround each of the plurality of first channel patterns CP3. The second gate structure GS4 may surround each of the plurality of second channel patterns CP4. The first and second gate structures GS3 and GS4 may be extended in the second direction DR2. Although not shown, the plurality of first gate structures GS3 may be positioned spaced apart in the first direction DR1. Also, although not shown, the plurality of second gate structures GS4 may be positioned spaced apart in the first direction DR1.

According to some embodiments, the first gate structure GS3 may include a plurality of first sub-gate structures S_GS3 and a first main gate structure M_GS3. According to some embodiments, the second gate structure GS4 may include a plurality of second sub-gate structures S_GS4 and a second main gate structure M_GS4. The plurality of first and second sub-gate structures S_GS3 and S_GS4 may be positioned between the plurality of first and second channel patterns CP3 and CP4 adjacent to each other in the third direction DR3 and between the first and second lower patterns BP3 and BP4 and the lowermost first and second channel patterns CP3 and CP4. The first and second main gate structures M_GS3 and M_GS4 may be positioned on (e.g., above) the first and second channel patterns CP3 and CP4, which are positioned at the top, respectively.

In detail, the plurality of first sub-gate structures S_GS3 may be positioned between the upper surface of the first lower pattern BP3 and the bottom surface of the lowermost first channel pattern CP3 and between the upper surface of the first channel pattern CP3 and the bottom surface of the first channel pattern CP3 facing in the third direction DR3. The plurality of second sub-gate structures S_GS4 may be positioned between the upper surface of the second lower pattern BP4 and the bottom surface of the lowermost second channel pattern CP4, and between the upper surface of the second channel pattern CP4 and the bottom surface of the second channel pattern CP4 facing in the third direction DR3.

The plurality of first and second sub-gate structures S_GS3 and S_GS4 may be adjacent to the first and second source/drain patterns 350 and 450, respectively. In this case, other components (e.g., first and second internal gate spacers 321 and 421) may be positioned between the plurality of first and second sub-gate structures S_GS3 and S_GS4 and the first and second source/drain patterns 350 and 450. The first and second main gate structures M_GS3 and M_GS4 may be positioned on (e.g., above) the plurality of first and second sub-gate structures S_GS3 and S_GS4 and the first and second channel patterns CP3 and CP4, respectively.

According to some embodiments, the first and second activation patterns AP3 and AP4 may include a plurality of first and second channel patterns CP3 and CP4, respectively, and the first and second gate structures GS3 and GS4 include a plurality of first and second sub-gate structures S_GS3 and S_GS4, respectively. At this time, the number of the plurality of first and second sub-gate structures S_GS3 and S_GS4 may be proportional to the number of the plurality of first and second channel patterns CP3 and CP4 included in the first and second activation patterns AP3 and AP4, respectively. For example, the number of plurality of first and second sub-gate structures S_GS3 and S_GS4 may be equal to the number of plurality of first and second channel patterns CP3 and CP4, respectively. For example, as shown in FIG. 12, the plurality of first and second sub-gate structures S_GS3 and S_GS4 may be three. However, the present disclosure is not limited thereto, and the plurality of first and second sub-gate structures S_GS3 and S_GS4 may include four or more first and second sub-gate structures S_GS3 and S_GS4, respectively.

Each of the plurality of first sub-gate structures S_GS3 may include a first sub-gate electrode 320S and a first sub-gate insulating layer 330S. Each of the plurality of second sub-gate structures S_GS4 may include a second sub-gate electrode 420S and a second sub-gate insulating layer 430S.

The first and second sub-gate electrodes 320S and 420S may be placed on the first and second lower patterns BP3 and BP4. The first and second sub-gate electrodes 320S and 420S and the first and second main gate electrodes 320M and 420M may surround a plurality of first and second channel patterns CP3 and CP4.

According to some embodiments, the side of the first sub-gate structure S_GS3 and the first channel patterns CP3 may be covered by the first main gate structures M_GS3. According to some embodiments, the side of the second sub-gate structure S_GS4 and the second channel patterns CP4 may be covered by the second main gate structure M_GS4.

According to some embodiments, at least a portion of the first sub-gate electrode 320S and the first main gate electrode 320M may be positioned on the stacking structure of the first sub-gate electrode 320S and the plurality of first channel patterns CP3. Another part of the first sub-gate electrode 320S and the first main gate electrode 320M may be formed to be on (e.g., to cover) both sides of the stacking structure of the first sub-gate electrode 320S and the plurality of first channel patterns CP3. At this time, the four surfaces of the plurality of first channel patterns CP3 may be surrounded by the first sub-gate electrode 320S and the first main gate electrode 320M.

At least a portion of the second sub-gate electrode 420S and the second main gate electrode 420M may be positioned on the stacking structure of the second sub-gate electrode 420S and the plurality of second channel patterns CP4. Another part of the second sub-gate electrode 420S and the second main gate electrode 420M may be formed to be on (e.g., to cover) both sides of the stacking structure of the second sub-gate electrode 420S and the plurality of second channel patterns CP4. At this time, the four surfaces of the plurality of second channel patterns CP4 may be surrounded by the second sub-gate electrode 420S and the second main gate electrode 420M.

The first and second sub-gate electrodes 320S and 420S may include at least one of a metal, a metal alloy, a conductive metal nitride, a metal silicide, a doped semiconductor material, a conductive metal oxide, or a conductive metal oxynitride. The first and second sub-gate electrodes 320S and 420S, for example, may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but are not limited thereto. The conductive metal oxide and the conductive metal oxynitride may include oxidized forms of the above-mentioned materials, but are not limited thereto.

The first and second sub-gate insulating layers 330S and 430S may surround the first and second sub-gate electrodes 320S and 420S, respectively. The first and second sub-gate insulating layers 330S and 430S may be positioned on (e.g., above) the first and second channel patterns CP3 and CP4, respectively. For example, the first and second sub-gate insulating layers 330S and 430S may be in directly contact with the first and second channel patterns CP3 and CP4, respectively. For example, the first and second sub-gate insulating layers 330S and 430S may include silicon oxide, silicon oxidation nitride or silicon nitride. Also, for example, the first and second sub-gate insulating layers 330S and 430S may include a high dielectric constant material. Also, for example, the first and second sub-gate insulating layers 330S and 430S may include both silicon oxide and a high dielectric constant material. High dielectric constant materials may include materials with a dielectric constant greater than silicon oxide (SiO₂), such as hafnium oxide (HfO), aluminum oxide (AlO), or tantalum oxide (TaO).

Referring to FIGS. 12 and 13, the first internal gate spacer 321 on the first region R3 according to some embodiments may be positioned between the first source/drain pattern 350 and the first sub-gate structures S_GS3. According to some embodiments, the second internal gate spacer 421 on the second region R4 may be positioned between the second source/drain pattern 450 and the second sub-gate structure S_GS4.

Referring to FIGS. 12 and 13, according to some embodiments, the first internal gate spacer 321 may have a first length h1 along the third direction DR3. According to some embodiments, the second internal gate spacer 421 may have a second length h2 that is different from the first length h1 along the third direction DR3. For example, the first length h1 of the first internal gate spacer 321 may be greater than the second length h2 of the second internal gate spacer 421.

Referring to FIGS. 12 and 13, according to some embodiments, the first thickness T31 and the second thickness T41 of each of the first and second internal gate spacers 321 and 421 may be measured by being observed with a scanning electron microscope (SEM) or a scanning transmission electron microscope (STEM) on the cross-section of first and second channel patterns CP3 and CP4 cut parallel to the first direction DR1 and the third direction DR3, respectively. In the present disclosure, the first thickness T31 and the second thickness T41 are not fixed values and may vary depending on the measurement region.

According to some embodiments, when the first length h1 along the third direction DR3 of the first internal gate spacer 321 is different from the second length h2 along the third direction DR3 of the second internal gate spacer 421, the first thickness T31 of the first internal gate spacer 321 may be different from the second thickness T41 of the second internal gate spacer 421.

For example, as shown, if the first length h1 along the third direction DR3 of the first internal gate spacer 321 is greater than the second length h2 along the third direction DR3 of the second internal gate spacer 421, the first thickness T31 of the first internal gate spacer 321 may be smaller (i.e., less) than the second thickness T41 of the second internal gate spacer 421.

According to some embodiments, each of the first thickness T31 and the second thickness T41 of the first and second internal gate spacers 321 and 421 may gradually decrease from the edges of both sides toward the middle point along the third direction DR3. In other words, the first thickness T31 and the second thickness T41 of the first and second internal gate spacers 321 and 421 may decrease from upper and lower surfaces of the first and second internal gate spacers 321 and 421 toward a center portion (e.g., a center point) of the first and second internal gate spacers 321 and 421 in the third direction DR3. That is, the first thickness T31 and the second thickness T41 of the first and second internal gate spacers 321 and 421 may decrease toward the third direction DR3 and then increase again. Accordingly, the first thickness T31 and the second thickness T41 of the first and second internal gate spacers 321 and 421 may be largest at both edges along the third direction DR3 and smallest at the midpoint along the third direction DR3.

According to some embodiments, two surfaces of the first internal gate spacer 321 facing each other along the first direction DR1 may have an approximately concave shape. Specifically, two faces facing each other of the first internal gate spacer 321 along the first direction DR1 may have an approximately concave shape on the cross-section along the first direction DR1 and the third direction DR3 perpendicular to the first direction DR1 and the second direction DR2. For example, the first internal gate spacer 321 may include a side surface that is opposite to the first gate structure GS3 in the first direction DR1 and has a concave shape, with the concave shape recessed inward toward the first gate structure GS3. The side surface of the first internal gate spacer 321 having the concave shape may face the first source/drain pattern 350. For example, the second internal gate spacer 421 may include a side surface that is opposite to the second gate structure GS4 in the first direction DR1 and has a concave shape, with the concave shape recessed inward toward the second gate structure GS4. The side surface of the second internal gate spacer 421 having the concave shape may face the second source/drain pattern 450.

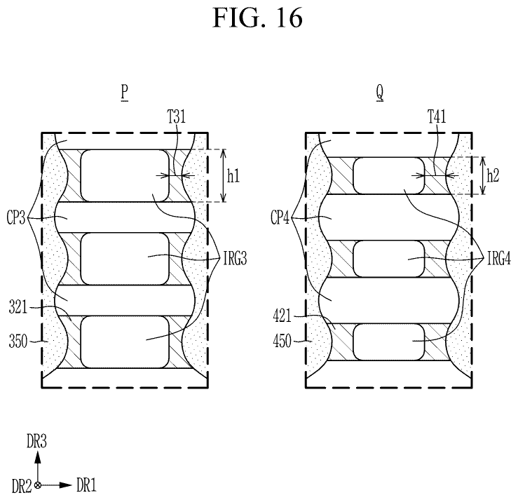

Detailed information about the first internal gate spacer 321 and the second internal gate spacer 421 having different thicknesses as the first internal gate spacer 321 and the second internal gate spacer 421 have different lengths along the third direction DR3 is described with reference to FIG. 16 later.

For example, the first and second internal gate spacers 321 and 421 may include silicon oxide (SiO₂).

According to some embodiments, the first and second main gate structures M_GS3 and M_GS4 may be positioned on (e.g., above) the first and second sub-gate structures S_GS3 and S_GS4 and the plurality of first and second channel patterns CP3 and CP4, respectively. The first and second main gate structures M_GS3 and M_GS4 may be positioned on the upper surface of the plurality of first and second channel patterns CP3 and CP4.

The first and second main gate structures M_GS3 and M_GS4 may include first and second main gate electrodes 320M and 420M, and first and second main gate insulating layers 330M and 430M, respectively.

The first and second main gate electrodes 320M and 420M may be positioned on the first and second sub-gate structures S_GS3 and S_GS4 and the plurality of first and second channel patterns CP3 and CP4, respectively. The first and second main gate electrodes 320M and 420M may be positioned on the upper surface of the plurality of first and second channel patterns CP3 and CP4. The first and second main gate electrodes 320M and 420M may be integrated with the first and second sub-gate electrodes 320S and 420S. The first and second main gate electrodes 320M and 420M may include the same material as the first and second sub-gate electrodes 320S and 420S. For example, the first and second main gate electrodes 320M and 420M may include at least one of a metal, a metal alloy, a conductive metal nitride, a metal silicide, a doped semiconductor material, a conductive metal oxide, or a conductive metal oxynitride.

The first and second main gate insulating layers 330M and 430M may extend along the side and bottom surfaces of the first and second main gate electrodes 320M and 420M. The first and second main gate insulating layers 330M, and 430M may extend along the sides of the first and second gate spacers 340 and 440. For example, the first and second main gate insulating layers 330M and 430M may include silicon oxide, silicon oxidation nitride or silicon nitride. Also, for example, the first and second main gate insulating layers 330M and 430M may include a high dielectric constant material. Also, for example, the first and second main gate insulating layers 330M and 430M may include both silicon oxide and a high dielectric constant material.

The semiconductor device according to some embodiments may further include first and second gate spacers 340 and 440, and first and second capping layers 345 and 445 in the first region R3 and the second region R4, respectively.

According to some embodiments, the first and second gate spacers 340 and 440 may be positioned on both (i.e., opposing) sides of the first and second main gate electrodes 320M and 420M, respectively. The first and second gate spacers 340 and 440 may not be placed between the first and second lower patterns BP3 and BP4 and the plurality of first and second channel patterns CP3 and CP4, respectively. The first and second gate spacers 340 and 440 may not be placed between the plurality of first and second channel patterns CP3 and CP4 adjacent to each other in the third direction DR3.

According to some embodiments, the first and second gate spacers 340 and 340, for example, may include at least one of silicon nitride (SiN), silicon oxynitride (SiON), silicon oxide (SiO₂), silicon carbonate nitride (SiOCN), silicon boron nitride (SiBN), silicon oxyboron nitride (SiOBN), silicon oxycarbide (SiOC), or combinations thereof. The first and second gate spacers 340 and 440 are shown as a single layer, but this is only for better understanding and ease of description and the present disclosure is not limited thereto.

According to some embodiments, the first and second capping layers 345 and 445 may be positioned on (e.g., above) the first and second main gate structures M_GS3 and M_GS4, respectively. The first and second capping layers 345 and 445 may be positioned on (e.g., above) the first and second main gate structures M_GS3 and M_GS4 and the first and second gate spacers 340 and 440. The upper surfaces of the first and second capping layers 345 and 445 may be placed on the same plane as (i.e., may be coplanar with) the upper surfaces of the first and second interlayer insulating layers 390 and 490, respectively.

The first and second capping layers 345 and 445 may include, for example, at least one of silicon nitride (SiN), silicon oxynitride (SiON), silicon (Si) carbonization nitride (SiCN), silicon carbonate nitride (SiOCN), or combinations thereof. The first and second capping layers 345 and 445 may include a material with an etch selectivity against the first and second interlayer insulating layers 390 and 490.

The first and second source/drain patterns 350 and 450 may be positioned on (e.g., above) the first and second lower patterns BP3 and BP4, respectively.

The first and second source/drain patterns 350 and 450 may be positioned between the first and second sub-gate structures S_GS3 and S_GS4 adjacent to each other in the first direction DR1. For example, the first and second source/drain patterns 350 and 450 may be positioned on both (i.e., opposing) sides of the first and second sub-gate structures S_GS3 and S_GS4.

The first and second source/drain patterns 350 and 450 may be positioned on the sides of the first and second channel patterns CP3 and CP4, respectively. For example, the first and second source/drain patterns 350 and 450 may be in contact with the sides of the first and second channel patterns CP3 and CP4, respectively. The first and second source/drain patterns 350 and 450 may be positioned between the first and second channel patterns CP3 and CP4, respectively, adjacent to each other in the first direction DR1.

According to some embodiments, the first and second source/drain patterns 350 and 450 may be in contact with the sides of the first and second internal gate spacers 321 and 421, respectively.

The sides of the first and second source/drain patterns 350 and 450 may have a bumpy embossing shape. In other words, the sides of the first and second source/drain patterns 350 and 450 may have a wavy profile. For example, the sides of the first and second source/drain patterns 350 and 450 adjacent to the first and second internal gate spacers 321 and 421 may have a roughly convex shape toward the first and second internal gate spacers 321 and 421, and the sides of the first and second source/drain patterns 350 and 450 adjacent to the first and second channel patterns CP3 and CP4 may have a roughly concave shape toward the first and second channel patterns CP3 and CP4.

According to some embodiments, the first and second source/drain patterns 350 and 450 may be epitaxial patterns formed by a selective epitaxial growth process using the first and second activation patterns AP3 and AP4 as seeds, respectively. The first and second source/drain patterns 350 and 450, according to some embodiments, may include at least one of silicon (Si) or silicon germanium (SiGe). The first and second channel patterns CP3 and CP4 may be parts of the first and second activation patterns AP3 and AP4 extending between the first and second source/drain patterns 350 and 450. The first and second source/drain patterns 350 and 450 may serve as a source/drain of a transistor that uses the first and second channel patterns CP3 and CP4 as channel regions.

The first and second source/drain patterns 350 and 450 may include first and second lower source/drain layers 351 and 451 and first and second upper source/drain layers 352 and 452, respectively. The first and second lower source/drain layers 351 and 451 may have a shape surrounding the side and bottom surfaces of the first and second upper source/drain layers 352 and 452, respectively.

The first and second channel patterns CP3 and CP4 may be in contact with the first and second lower source/drain layers 351 and 451, respectively, and may not be in contact with the first and second upper source/drain layers 352 and 452. Therefore, the first and second lower source/drain layers 351 and 451 may be positioned between the first and second channel patterns CP3 and CP4 and the first and second upper source/drain layers 352 and 452.

However, the present disclosure is not limited thereto, and at least some of the first and second channel patterns CP3 and CP4 may be in contact with the first and second upper source/drain layers 352 and 452, according to some embodiments. Additionally, the first and second source/drain patterns 350 and 450 may not be divided into first and second lower source/drain layers 351 and 451 and first and second upper source/drain layers 352 and 452, but may be formed as a single layer, according to some embodiments.

The first and second source/drain patterns 350 and 450 may include SiGe. The Ge content of the first and second lower source/drain layers 351 and 451 may be different from the Ge content of the first and second upper source/drain layers 352 and 452.

The first and second lower source/drain layers 351 and 451 may be made of SiGe including low concentration Ge, and the first and second upper source/drain layers 352 and 452 may be made of SiGe including high concentration Ge. However, the material of the first and second source/drain patterns 350 and 450 is not limited to this and may be changed in various ways.

According to some embodiments, the bottom surface of the first and second source/drain patterns 350 and 450 may be positioned at a lower level than the bottom surface of plurality of first and second sub-gate structures S_GS3 and S_GS4. For example, as shown in FIG. 12, the bottom surfaces of the first and second source/drain patterns 350 and 450 may be positioned closer to the bottom surfaces of the first and second lower patterns BP3 and BP4 than the bottom surfaces of the first and second sub-gate structures S_GS3 and S_GS4, which are positioned at the bottom.

According to some embodiments, the first and second etch stop layers 385 and 485 may be positioned on the sides of the first and second gate spacers 340 and 440 and on the upper surface of the first and second source/drain patterns 350 and 450, respectively.

The first and second etch stop layers 385 and 485 may include a material with an etch selectivity against the first and second interlayer insulating layers 390 and 490, which will be described later. The first and second etch stop layers 385 and 485, for example, may include silicon nitride (SiN), silicon oxynitride (SiON), silicon carbonate nitride (SiOCN), silicon boron nitride (SiBN), silicon acid oxyboron nitride (SiOBN), silicon oxycarbide (SiOC), or a combination thereof.

The first and second interlayer insulating layers 390 and 490 may be positioned on (e.g., above) the first and second etch stop layers 385 and 485, respectively. The first and second interlayer insulating layers 390 and 490 may be positioned on (e.g., above) the first and second source/drain patterns 350 and 450. The first and second interlayer insulating layers 390 and 490 may not be on (e.g., may not cover) the upper surface of the first and second capping layers 345 and 445.

The first and second interlayer insulating layers 390 and 490 may include at least one of, for example, silicon oxide (SiO₂), silicon nitride (SiN), silicon oxynitride (SiON), or low a dielectric constant material. The low dielectric constant material, for example, may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride silicate glass), polyimide nanofoams such as polypropylene oxide, CDO (Carbon Doped silicon Oxide), OSG (Organo silicate glass), SiLK, Amorphous Fluorinated Carbon, silica aerogels, silica xerogels, mesoporous silica, or a combination thereof, but is not limited thereto.

Referring to FIG. 13, the first and second sub-gate insulating layers 330S and 430S may include first and second horizontal parts 331S and 431S on the first and second channel patterns CP3 and CP4, first and second vertical parts 333S and 433S on the first and second internal gate spacers 321 and 421, and first and second corner parts 332S and 432S between the first and second horizontal parts 331S and 431S and the first and second vertical parts 333S and 433S. Here, the first and second vertical parts 333S and 433S may face the convex side of the first and second source/drain patterns 350 and 450 in the first direction DR1.

According to some embodiments, the first and second horizontal parts 331S and 431S, the first and second vertical parts 333S and 433S, and the first and second corner parts 332S and 432S between the first and second horizontal parts 331S and 431S and the first and second vertical parts 333S and 433S may be formed by being integrally connected.

According to some embodiments, the thickness of the first and second internal gate spacers 321 and 421 corresponding to the length from the point where the first and second vertical parts 333S and 433S and the first and second corner parts 332S and 432S are connected (i.e., are in contact) to the surface where the first and second internal gate spacers 321 and 421 are in contact with the first and second channel patterns CP3 and CP4 along the third direction DR3 may be a third thickness T32 and a fourth thickness T42.

According to some embodiments, the third thickness T32 may be less than half (½) the first average thickness, which is the average value of the thickness at the edge and center of the first internal gate spacer 321 along the third direction DR3. Specifically, the third thickness T32 may be less than half (½) the first average thickness, which is the average value of the first upper thickness T31a, the first central portion thickness T31b, and the first lower thickness T31c of the first internal gate spacer 321. More specifically, the third thickness T32 may be less than one-third (⅓) times of the first average thickness.

Here, the first upper thickness T31a may correspond to the thickness along the first direction DR1 at the upper part (i.e., upper portion) of the first internal gate spacer 321. Specifically, the first upper thickness T31a may correspond to the thickness of the first internal gate spacer 321 along the first direction DR1 at the point where the upper part of the first vertical part 333S and the first corner part 332S are connected. The first central portion thickness T31b may correspond to the thickness along the first direction DR1 at the midpoint of the first internal gate spacer 321 along the third direction DR3. The first lower thickness T31c may correspond to the thickness at the lower part (i.e., lower portion) of the first internal gate spacer 321 along the first direction DR1. Specifically, the first lower thickness T31c may correspond to the thickness of the first internal gate spacer 321 along the first direction DR1 at the point where the lower part of the first vertical part 333S and the first corner part 332S are connected.

According to some embodiments, the fourth thickness T42 may be less than half (½) of the second average thickness, which is the average value of the thickness at the edge and center of the second internal gate spacer 421 along the third direction DR3. Specifically, the fourth thickness T42 may be less than half (½) of the second average thickness, which is the average value of the second upper thickness T41a, the second central portion thickness T41b, and the second lower thickness T41c of the second internal gate spacer 421. More specifically, the fourth thickness T42 may be less than one-third (⅓) times of the second average thickness.

Here, the second upper thickness T41a may correspond to the thickness along the first direction DR1 at the upper part (i.e., upper portion) of the second internal gate spacer 421. Specifically, the second upper thickness T41a may correspond to the thickness of the second internal gate spacer 421 along the first direction DR1 at the point where the upper part of the second vertical part 433S and the second corner part 432S are connected. The second central portion thickness T41b may correspond to the thickness along the first direction DR1 at the midpoint along the third direction DR3 of the second internal gate spacer 421. The second lower thickness T41c may correspond to the thickness at the lower part (i.e., lower portion) of the second internal gate spacer 421 along the first direction DR1. Specifically, the second lower thickness T41c may correspond to the thickness of the second internal gate spacer 421 along the first direction DR1 at the point where the lower part of the second vertical part 433S and the second corner part 432S are connected.

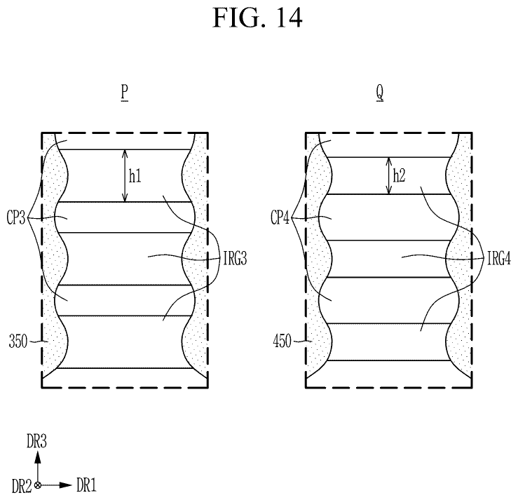

FIGS. 14 to 18 are enlarged views to explain a method of forming a region P and a region Q of FIG. 12 according to some further embodiments.

Although not shown, a structure may be formed by alternately stacking a sacrificial layer and a semiconductor material layer on a first region R3 and a second region R4, respectively, and then patterning them to form a first and second source/drain recess (not shown). After forming the first and second source/drain patterns 350 and 450 within the first and second source/drain recess (not shown), the sacrificial layer may be removed to form the first and second internal spaces IRG3 and IRG4.

According to some embodiments, the sacrificial layer is made of a material with high selectivity against the first and second channel patterns CP3 and CP4 and the first and second source/drain patterns 350 and 450. For example, the sacrificial layer may be made of SiGe, the first and second channel patterns CP3 and CP4 may be made of Si, and the first and second source/drain patterns 350 and 450 may be made of SiGe. At this time, the etching process may be performed using an etching solution that has a relatively high etch rate for silicon oxide. Therefore, the sacrificial layer is removed, and the first and second channel patterns CP3 and CP4 and the first and second source/drain patterns 350 and 450 remain. Accordingly, as shown in FIG. 14, the first and second internal spaces IRG3 and IRG4 may be formed in the area where the sacrificial layer is removed.

As the first and second internal spaces IRG3 and IRG4 are formed, at least a portion of the sides of the first and second source/drain patterns 350 and 450 may be exposed. Additionally, the upper and/or lower surfaces of the first and second channel patterns CP3 and CP4 may be exposed by the first and second internal spaces IRG3 and IRG4. Accordingly, the first and second internal spaces IRG3 and IRG4 may be surrounded by the first and second channel patterns CP3 and CP4 and the first and second source/drain patterns 350 and 450.

According to some embodiments, the first internal spaces IRG3 may have a first length h1 along the third direction DR3. According to some embodiments, the second internal spaces IRG4 may have a second length h2 that is different from the first length h1 along the third direction DR3. For example, the first length h1 of the first internal spaces IRG3 may be greater than the second length h2 of the second internal spaces IRG4.

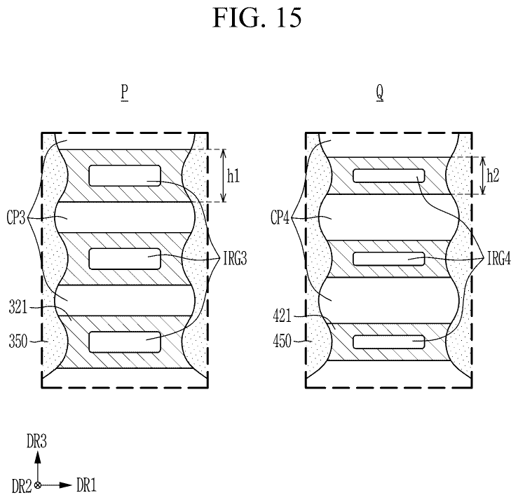

Referring to FIG. 15, according to some embodiments, first and second internal gate spacers 321 and 421 may be formed within the first and second internal spaces IRG3 and IRG4. According to some embodiments, the deposition of the first and second internal gate spacers 321 and 421 may be performed in the same process, but the present disclosure is not limited thereto.

The first and second internal gate spacers 321 and 421 may be formed using an atomic layer deposition (ALD) process, a chemical vapor deposition (CVD) process, and/or a physical vapor deposition (PVD) process, but the present disclosure is not limited thereto.

According to some embodiments, the first and second internal gate spacers 321 and 421 may be conformally formed within the first and second internal spaces IRG3 and IRG4, respectively. In other words, the first and second internal gate spacers 321 and 421 may be formed on the exposed surface of the first and second channel patterns CP3 and CP4 and the exposed surface of the first and second source/drain patterns 350 and 450, respectively.

According to some embodiments, the first and second internal gate spacers 321 and 421 may be formed to partially fill the first and second internal spaces IRG3 and IRG4, respectively, rather than completely filling them.

According to some embodiments, the first and second internal gate spacers 321 and 421 may have a roughly convex or flat shape with the surface in contact with the first and second internal spaces IRG3 and IRG4 toward the first and second internal spaces IRG3 and IRG4, and the first and second internal gate spacers 321 and 421 may have a roughly concave or flat shape with the surface in contact with the first and second source/drain patterns 350 and 450 toward the first and second source/drain patterns 350 and 450.

The first and second internal gate spacers 321 and 421 may include a low dielectric constant material. The low dielectric constant material may include silicon oxide or a material with a dielectric constant lower than silicon oxide. For example, the low dielectric constant material may include silicon oxide, silicon oxide doped with fluorine or carbon, porous silicon oxide, organic polymeric dielectric, or combinations thereof.

Referring to FIG. 16, according to some embodiments, the first and second internal gate spacers 321 and 421 may be removed (e.g., may be partially removed) through an etching process. According to some embodiments, the etching of the first and second internal gate spacers 321 and 421 may be performed in the same process, but the present disclosure is not limited thereto.

According to some embodiments, etching the first and second internal gate spacers 321 and 421 may include a wet etching process using an etching solution that selectively etches only the first and second internal gate spacers 321 and 421. Specifically, the etching material may be provided through the first and second internal spaces IRG3 and IRG4 to etch the first and second internal gate spacers 321 and 421.

According to some embodiments, the etching process may be performed until the surfaces of the first and second channel patterns CP3 and CP4 are exposed. Still referring to FIG. 16 and referring back to FIGS. 12 and 13, as described above, the distance between the first channel patterns CP3 and the distance between the second channel patterns CP4 may be different. In other words, the first length h1 of the first internal spaces IRG3 along the third direction DR3 may be different from the second length h2 of the second internal spaces IRG4 along the third direction DR3.

Accordingly, the amount of the etching of the first and second internal gate spacers 321 and 421 along the first direction DR1 may be different. Specifically, as the etching process is performed until the surfaces of the first and second channel patterns CP3 and CP4 are exposed, when the first length h1 of the first internal spaces IRG3 along the third direction DR3 and the second length h2 of second internal spaces IRG4 along the third direction DR3 are different, the etching amount of the first internal gate spacer 321 along the first direction DR1 may be different from the etching amount of the second internal gate spacer 421 along the first direction DR1.

For example, if the first length h1 of first internal spaces IRG3 along the third direction DR3 is greater than the second length h2 of second internal spaces IRG4 along the third direction DR3, the etching amount of the first internal gate spacer 321 along the first direction DR1 may be greater than the etching amount of the second internal gate spacer 421 along the first direction DR1.

Accordingly, as shown in FIG. 16, the first thickness T31 of the first internal gate spacer 321 along the first direction DR1 may be smaller than the second thickness T41 of the second internal gate spacer 421 along the first direction DR1.

According to some embodiments, after the etching process, the first and second internal gate spacers 321 and 421 may remain on the surface of the first and second source/drain patterns 350 and 450, respectively. The remaining first and second internal gate spacers 321 and 421 may provide the first and second internal spaces IRG3 and IRG4 expanded compared with FIG. 15.

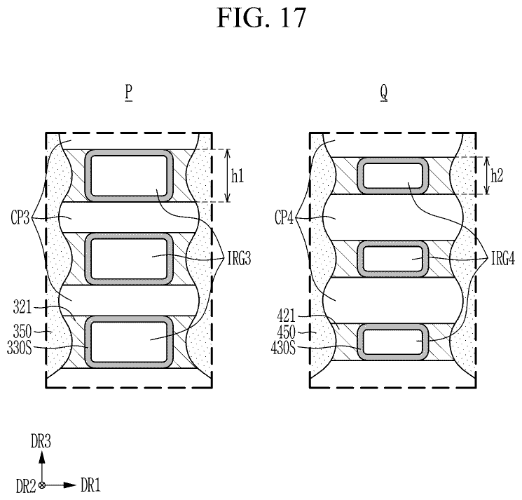

Referring to FIG. 17, according to some embodiments, first and second sub-gate insulating layers 330S and 430S may be formed within the first and second internal spaces IRG3 and IRG4.

According to some embodiments, the first and second sub-gate insulating layers 330S and 430S may be formed using an atomic layer deposition (ALD) process, a chemical vapor deposition (CVD) process, and/or a physical vapor deposition (PVD) process, but the present disclosure is not limited thereto.

According to some embodiments, the first and second sub-gate insulating layers 330S and 430S may be conformally formed within the first and second internal spaces IRG3 and IRG4, respectively. In other words, the first and second sub-gate insulating layers 330S and 430S may each have a uniform thickness. According to some embodiments, the first and second sub-gate insulating layers 330S and 430S may be formed on the first and second internal gate spacers 321 and 421, respectively.

Additionally, according to some embodiments, the first and second sub-gate insulating layers 330S and 430S may be formed on the first and second channel patterns CP3 and CP4, respectively. Specifically, first and second sub-gate insulating layers 330S and 430S may be formed on the first and second internal gate spacers 321 and 421 along the first direction DR1, respectively, and on the first and second channel patterns CP3 and CP4 along third direction DR3.

For example, the first and second sub-gate insulating layers 330S and 430S may include silicon oxide, silicon oxidation nitride or silicon nitride. Also, for example, the first and second sub-gate insulating layers 330S and 430S may include a high dielectric constant material. Also, for example, the first and second sub-gate insulating layers 330S and 430S may include both silicon oxide and a high dielectric constant material. High dielectric constant materials may include materials with a dielectric constant greater than silicon oxide (SiO₂), such as hafnium oxide (HfO), aluminum oxide (AlO), or tantalum oxide (TaO).

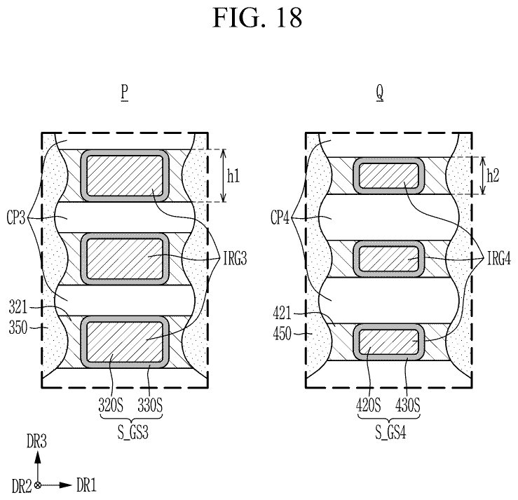

Referring to FIG. 18, first and second sub-gate electrodes 320S and 420S may be formed on the first and second sub-gate insulating layers 330S and 430S according to some embodiments.

According to some embodiments, first and second sub-gate electrodes 320S and 420S may be formed to be in (e.g., to fill) the first and second internal spaces IRG3 and IRG4.

The first and second sub-gate electrodes 320S and 420S may be formed using an atomic layer deposition (ALD) process, a chemical vapor deposition (CVD) process, etc. The first and second sub-gate electrodes 320S and 420S may include a doped polysilicon, a metal, conductive metal nitride, a conductive metal carbide, or a combination thereof. However, this is only an example, and the material of the first and second sub-gate electrodes 320S and 420S is not limited thereto.

In the semiconductor device according to some embodiments of the present disclosure as described above, by varying the thickness of the first and second internal gate spacers 321 and 421 according to the distance between first channel patterns CP3 on the first region R3 and the distance between second channel patterns CP4 on the second region R4, the reliability may be secured according to the characteristics of each region.

For example, in the semiconductor device according to some embodiments of the present disclosure, by varying the thickness of the first and second internal gate spacers 321 and 421 depending on whether the AC characteristic is an important element region or the DC characteristic is an important element region, the reliability according to the characteristic of each region may be secured.

While the present disclosure has been described in connection with reference to example embodiments thereof, it will be understood that the present disclosure is not limited to the described embodiments, but, on the contrary, is intended to cover various modifications and equivalent arrangements included within the scope of the appended claims.

What is claimed is:

1. A semiconductor device comprising:
a substrate including a first region and a second region;
first source/drain patterns spaced apart from each other in a first direction on the first region of the substrate;
first channel patterns between the first source/drain patterns;
a first gate structure at least partially surrounding the first channel patterns and extending in a second direction intersecting the first direction, wherein the first channel patterns are spaced apart from each other in a third direction perpendicular to the first and second directions;
second source/drain patterns spaced apart from each other in the first direction on the second region of the substrate;
second channel patterns spaced apart from each other in the third direction and between the second source/drain patterns;
a second gate structure at least partially surrounding the second channel patterns and extending in the second direction;
a first internal gate spacer between the first gate structure and a first one of the first source/drain patterns; and
a second internal gate spacer between the second gate structure and a first one of the second source/drain patterns,
wherein the first internal gate spacer has a first thickness in the first direction, and the second internal gate spacer has a second thickness in the first direction,
wherein the first thickness of the first internal gate spacer at a center point thereof along the second direction is different from the second thickness of the second internal gate spacer at a center point thereof along the second direction,
wherein the first internal gate spacer includes a side surface that faces the first one of the first source/drain patterns in the first direction and has a concave shape in a cross-sectional view, and
wherein the second internal gate spacer includes a side surface that faces the first one of the second source/drain patterns in the first direction and has a concave shape in a cross-sectional view.

2. The semiconductor device of claim 1, wherein:
the first gate structure includes a first gate electrode on a first one of the first channel patterns and a first gate insulating layer at least partially surrounding the first gate electrode,
the first gate insulating layer includes a first horizontal part between the first one of the first channel patterns and the first gate electrode, a first vertical part between the first internal gate spacer and the first gate electrode, and a first corner part between the first horizontal part and the first vertical part,
a third thickness of the first internal gate spacer, corresponding to a length in the third direction from a point where the first vertical part and the first corner part are in contact to a surface where the first internal gate spacer is in contact with the first one of the first channel patterns, is less than half of an average value of thicknesses in the first direction at an upper portion, a lower portion, and a center portion of the first internal gate spacer along the third direction,
the second gate structure includes a second gate electrode on a first one of the second channel patterns and a second gate insulating layer at least partially surrounding the second gate electrode,
the second gate insulating layer includes a second horizontal part between the first one of the second channel patterns and the second gate electrode, a second vertical part between the second internal gate spacer and the second gate electrode, and a second corner part between the second horizontal part and the second vertical part, and
a fourth thickness of the second internal gate spacer, corresponding to a length in the third direction from a point where the second vertical part and the second corner part are in contact to a surface where the second internal gate spacer is in contact with the first one of the second channel patterns, is less than half of an average value of thicknesses in the first direction at an upper portion, a lower portion, and a center portion of the second internal gate spacer along the third direction.

3. The semiconductor device of claim 1, wherein:
the first thickness of the first internal gate spacer decreases toward a center point thereof along the third direction, and
the second thickness of the second internal gate spacer decreases toward a center point thereof along the third direction.

4. The semiconductor device of claim 1, wherein:
at least one of the first channel patterns has a first width in the second direction, and at least one of the second channel patterns has a second width in the second direction that is greater than the first width, and
the second thickness of the second internal gate spacer at the center point thereof along the second direction is greater than the first thickness of the first internal gate spacer at the center point thereof along the second direction.

5. The semiconductor device of claim 4, wherein the first thickness of the first internal gate spacer at an edge thereof along the second direction is equal to the second thickness of the second internal gate spacer at an edge thereof along the second direction.

6. The semiconductor device of claim 1, wherein:
at least one of the first channel patterns has a first width in the second direction, and at least one of the second channel patterns has a second width in the second direction that is different from the first width, and
a difference between the first thickness of the first internal gate spacer at the center point thereof and an edge thereof along the second direction is different from a difference between the second thickness of the second internal gate spacer at the center point thereof and an edge thereof along the second direction.

7. The semiconductor device of claim 1, wherein:
the first internal gate spacer has a first length in the third direction, and
the second internal gate spacer has a second length in the third direction that is different from the first length.

8. The semiconductor device of claim 7, wherein:
the first length of the first internal gate spacer in the third direction is greater than the second length of the second internal gate spacer in the third direction, and
the first thickness of the first internal gate spacer at the center point thereof along the second direction is less than the second thickness of the second internal gate spacer at the center point thereof along the second direction.

9. A method of manufacturing a semiconductor device comprising:
forming first source/drain patterns spaced apart from each other in a first direction on a first region of a substrate, and second source/drain patterns spaced apart from each other in the first direction on a second region of the substrate;
forming first channel patterns between the first source/drain patterns and having a first width in a second direction intersecting the first direction, and second channel patterns between the second source/drain patterns and having a second width in the second direction that is different from the first width;
forming first internal spaces at least partially surrounded by the first source/drain patterns, and second internal spaces at least partially surrounded by the second source/drain patterns;
forming a first internal gate spacer on a side surface of a first one of the first source/drain patterns and in a first one of the first internal spaces, and a second internal gate spacer on a side surface of a first one of the second source/drain patterns and in a first one of the second internal spaces, the first internal gate spacer and the second internal gate spacer having a first thickness and a second thickness, respectively, in the first direction; and
forming a first gate electrode in the first internal spaces, and a second gate electrode in the second internal spaces,
wherein the first thickness of the first internal gate spacer at a center point thereof along the second direction is different from the second thickness of the second internal gate spacer at a center point thereof along the second direction.

10. The method of claim 9, wherein:
the first internal gate spacer includes a side surface that faces the first one of the first source/drain patterns in the first direction and has a concave shape in a cross-sectional view, and
the second internal gate spacer includes a side surface that faces the first one of the second source/drain patterns in the first direction and has a concave shape in a cross-sectional view.

11. The method of claim 9, wherein:
the first thickness of the first internal gate spacer decreases toward a center point thereof along a third direction perpendicular to the first and second directions, and
the second thickness of the second internal gate spacer decreases toward a center point thereof along the third direction.

12. The method of claim 9, further comprising:
forming a first gate insulating layer in the first internal spaces; and
forming a second gate insulating layer in the second internal spaces,
wherein the first gate insulating layer includes a first horizontal part between a first one of the first channel patterns and the first gate electrode, a first vertical part between the first internal gate spacer and the first gate electrode, and a first corner part between the first horizontal part and the first vertical part,
wherein a third thickness of the first internal gate spacer, corresponding to a length in a third direction perpendicular to the first and second directions from a point where the first vertical part and the first corner part are in contact to a surface where the first internal gate spacer is in contact with the first one of the first channel patterns, is less than half of an average value of thicknesses in the first direction at an upper portion, a lower portion, and a center portion of the first internal gate spacer along the third direction,
wherein the second gate insulating layer includes a second horizontal part between a first one of the second channel patterns and the second gate electrode, a second vertical part between the second internal gate spacer and the second gate electrode, and a second corner part between the second horizontal part and the second vertical part, and
wherein a fourth thickness of the second internal gate spacer, corresponding to a length in the third direction from a point where the second vertical part and the second corner part are in contact to a surface where the second internal gate spacer is in contact with the first one of the second channel patterns, is less than half of an average value of thicknesses in the first direction at an upper portion, a lower portion, and a center portion of the second internal gate spacer along the third direction.

13. The method of claim 9, wherein:
the second width of the second channel patterns is greater than the first width of the first channel patterns, and
the second thickness of the second internal gate spacer at the center point thereof along the second direction is greater than the first thickness of the first internal gate spacer at the center point thereof along the second direction.

14. The method of claim 13, wherein the first thickness of the first internal gate spacer at an edge thereof along the second direction is equal to the second thickness of the second internal gate spacer at an edge thereof along the second direction.

15. The method of claim 9, wherein:
the second width of the second channel patterns is greater than the first width of the first channel patterns, and
a difference between the first thickness of the first internal gate spacer at the center point thereof and an edge thereof along the second direction is different from a difference between the second thickness of the second internal gate spacer at the center point thereof and an edge thereof along the second direction.

16. A method of manufacturing a semiconductor device comprising:
forming first source/drain patterns spaced apart from each other in a first direction on a first region of a substrate, and second source/drain patterns spaced apart from each other in the first direction on a second region of the substrate;
forming first internal spaces at least partially surrounded by first channel patterns between the first source/drain patterns and having a first length in a third direction perpendicular to an upper surface of the substrate, and second internal spaces at least partially surrounded by second channel patterns between the second source/drain patterns and having a second length in the third direction that is different from the first length;
forming a first internal gate spacer on a side surface of a first one of the first source/drain patterns and in a first one of the first internal spaces, and a second internal gate spacer on a side surface of a first one of the second source/drain patterns and in a first one of the second internal spaces, the first internal gate spacer and the second internal gate spacer having a first thickness and a second thickness, respectively, in the first direction; and
forming a first gate electrode in the first internal spaces, and a second gate electrode in the second internal spaces,
wherein the first thickness of the first internal gate spacer at a center point thereof along a second direction intersecting the first direction is different from the second thickness of the second internal gate spacer at a center point thereof along the second direction.

17. The method of claim 16, wherein:
the first internal gate spacer includes a side surface that faces the first one of the first source/drain patterns in the first direction and has a concave shape in a cross-sectional view, and
the second internal gate spacer includes a side surface that faces the first one of the second source/drain patterns in the first direction and has a concave shape in a cross-sectional view.

18. The method of claim 16, wherein:
the first thickness of the first internal gate spacer decreases toward a center point thereof along the third direction, and
the second thickness of the second internal gate spacer decreases toward a center point thereof along the third direction.

19. The method of claim 16, wherein:
the first length of the first internal spaces in the third direction is greater than the second length of the second internal spaces in the third direction, and
the first thickness of the first internal gate spacer at the center point thereof along the second direction is less than the second thickness of the second internal gate spacer at the center point thereof along the second direction.

20. The method of claim 16, further comprising:
forming a first gate insulating layer in the first internal spaces; and
forming a second gate insulating layer in the second internal spaces,
wherein the first gate insulating layer includes a first horizontal part between a first one of the first channel patterns and the first gate electrode, a first vertical part between the first internal gate spacer and the first gate electrode, and a first corner part between the first horizontal part and the first vertical part,
wherein a third thickness of the first internal gate spacer, corresponding to a length in the third direction from a point where the first vertical part and the first corner part are in contact to a surface where the first internal gate spacer is in contact with the first one of the first channel patterns, is less than half of an average value of thicknesses in the first direction at an upper portion, a lower portion, and a center portion of the first internal gate spacer along the third direction,
wherein the second gate insulating layer includes a second horizontal part between a first one of the second channel patterns and the second gate electrode, a second vertical part between the second internal gate spacer and the second gate electrode, and a second corner part between the second horizontal part and the second vertical part, and
wherein a fourth thickness of the second internal gate spacer, corresponding to a length in the third direction from a point where the second vertical part and the second corner part are in contact to a surface where the second internal gate spacer is in contact with the first one of the second channel patterns, is less than half of an average value of thicknesses in the first direction at an upper portion, a lower portion, and a center portion of the second internal gate spacer along the third direction.
